(19) United States
(12) Patent Application Publication
(10) Pub. No.: US 2023/0154772 A1
(43) Pub. Date: May 18, 2023

(54) SLIDE AND PIVOT ASSEMBLIES FOR PROCESS MODULE BIAS ASSEMBLIES OF SUBSTRATE PROCESSING SYSTEMS

(71) Applicant: LAM RESEARCH CORPORATION, Fremont, CA (US)

(72) Inventors: David William PAQUET, Fremont, CA (US); Dexter Yuk Hing CHONG, San Jose, CA (US); Michael C. KELLOGG, Oakland, CA (US); Bin YUAN, Monte Sereno, CA (US)

(21) Appl. No.: 17/916,852

(22) PCT Filed: Mar. 29, 2021
(86) PCT No.: PCT/US2021/024563

§ 371 Date: Oct. 4, 2022

Related U.S. Application Data
(60) Provisional application No. 63/005,688, filed on Apr. 6, 2020.

(51) Int. Cl. H01L 21/67; H01J 37/32

(52) U.S. Cl. CPC H01L 21/6719; H01J 37/32788; H01J 37/32743; H01J 37/32807; H01J 37/3288; H01L 21/67173; H01L 21/67178

(57) ABSTRACT

A slide and pivot assembly for a process module bias assembly of a substrate processing system includes a slide torsion plate, one or more rails and bearings, a bias mounting plate, and a hinge assembly. The one or more rails and bearings are attached to the slide torsion plate or a processing chamber. The bias mounting plate is configured to hold a portion of a process module for processing a substrate. The hinge assembly is attached to the slide torsion plate and the bias mounting plate. The slide torsion plate, the bias mounting plate and the hinge assembly are configured to slide via the one or more rails and bearings in a lateral direction relative to the processing chamber. The bias mounting plate is configured to pivot relative to the slide torsion plate while the slide and pivot assembly is in at least a partially pulled out state.

### CROSS-REFERENCE TO RELATED APPLICATIONS

This application claims the benefit of U.S. Provisional Application No. 63/005,688, filed on Apr. 6, 2020. The entire disclosure of the application referenced above is incorporated herein by reference.

### FIELD

The present disclosure relates to a slide and pivot assembly to allow access to a process module and an interior of a processing chamber of a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, and/or other etch, deposition, or cleaning processes. A substrate may be arranged on a substrate support, such as a pedestal, an electrostatic chuck (ESC), etc. in a processing chamber of the substrate processing system. During etching, gas mixtures including one or more precursors may be introduced into the processing chamber and plasma may be used to initiate chemical reactions.

### SUMMARY

A slide and pivot assembly for a process module bias assembly of a substrate processing system is provided. The slide and pivot assembly includes: a slide torsion plate; one or more rails and bearings configured to attach to the slide torsion plate or a processing chamber; a bias mounting plate configured to hold a portion of a process module for processing a substrate; and a hinge assembly attached to the slide torsion plate and the bias mounting plate. The slide torsion plate, the bias mounting plate and the hinge assembly are configured to slide via the one or more rails and bearings in a lateral direction relative to the processing chamber. The bias mounting plate is configured to pivot relative to the slide torsion plate while the slide and pivot assembly is in at least a partially pulled out state.

In other features, the hinge assembly includes: a first hinge member attached to the slide torsion plate; and a second hinge member attached to the bias mounting plate and connected to pivot relative to the first hinge member. The bias mounting plate and the second hinge member are configured to pivot relative to the slide torsion plate and the first hinge member while the slide and pivot assembly is in a fully pulled out state.

In other features, the slide and pivot assembly further includes a pin attached to the slide torsion plate. The first hinge member is configured to rotate relative to the pin to compensate for sag in the bias mounting plate. In other features, the hinge assembly includes one or more adjustment screws for adjusting a tilt angle of the first hinge member relative to the slide torsion plate.

In other features, the slide and pivot assembly further includes a motion interlock mechanism attached to the slide torsion plate and configured to: hold the slide torsion plate, the hinge assembly and the bias mounting plate in a pulled out state relative to the processing chamber; and permit the slide torsion plate, the hinge assembly and the bias mounting plate to be slid from a pulled out position to a pushed in position if a predetermined amount of lateral force is applied on the bias mounting plate.

In other features, the motion interlock mechanism is configured to: prevent the second hinge member and the bias mounting plate from pivoting relative to the first hinge member and slide torsion plate when in an engaged state; and permit the second hinge member and the bias mounting plate to pivot relative to the first hinge member and slide torsion plate when in a disengaged state.

In other features, the motion interlock mechanism includes: an attachment bar attached to the slide torsion plate; a latch bar; and a spring configured to rotate the latch bar relative to the attachment bar to a disengaged position when the slide torsion plate is in a pulled out state.

In other features, the motion interlock mechanism further includes a catch bracket attached to the second hinge member; and the latch bar. The latch bar is configured to: engage with the catch bracket when the bias mounting plate is in a fully non-rotated state and the slide torsion plate is pushed in from a fully pulled out position; and disengage with the catch bracket when the slide torsion plate is pulled out to the fully pulled out position.

In other features, the motion interlock mechanism further comprises a toggle stop bracket and a spring. The latch bar includes a stop flange or pin. The spring slides the toggle stop bracket to contact the latch bar, which prevents rotation of the latch bar from a slide locked position and prevents engagement of the latch bar with the catch bracket when the second hinge member is pivoted away from a closed position. The second hinge member, when transitioned to the closed position, pushes the toggle stop bracket, which compresses the spring and moves the toggle stop bracket to allow rotation of the latch bar out of the slide locked position and to allow engagement of the latch bar with the catch bracket.

In other features, the one or more rails includes two rails mounted on the slide torsion plate configured to ride on bearing blocks mounted on the processing chamber. In other features, the hinge assembly includes a pivot lock assembly for locking the hinge assembly in a plurality of states including a closed state and an open state.

In other features, the slide and pivot assembly further includes a slide lock assembly for locking the slide torsion plate relative to the processing chamber in a plurality of states including a pushed in state and a pulled out state. In other features, the slide lock assembly includes a plunger and roller that extends into notches in the slide torsion plate. In other features, the bias mounting plate closes off an open side of the processing chamber.

In other features, the slide and pivot assembly further includes a jack screw assembly attached to the bias mounting plate and configured to detach the bias mounting plate from the processing chamber. In other features, the jack screw assembly includes: a jack screw block attached to the bias mounting plate; and a jack screw extending into the jack screw block and through the bias mounting plate and coupling to the processing chamber.

In other features, the jack screw block has two positions relative to the jack screw including a first position associated with attaching the bias mounting plate to the processing chamber and a second position associated with jacking the bias mounting plate off of the processing chamber.

In other features, the slide and pivot assembly further includes: an alignment pin; and a bushing configured to receive the alignment pin. The jack screw is configured to when turned (i) pull or push the alignment pin into the bushing to align the bias mounting plate relative to the processing chamber, and (ii) release the alignment pin from the bushing when opening the processing chamber.

In other features, the slide and pivot assembly further including: one or more alignment pins attached to the processing chamber or the bias mounting plate; and one or more bushings to receive respectively the one or more alignment pins. The one or more alignment pins, when received in the one or more bushing, align the bias mounting plate to the processing chamber.

In other features, the hinge assembly includes one or more bearing assemblies. In other features, a substrate processing system is provided and includes the slide and pivot assembly, the processing chamber, and a substrate support attached to the bias mounting plate and configured to hold the substrate.

In other features, the slide and pivot assembly further includes: cam followers configured to attach to the processing chamber; and brackets configured to attach to the processing chamber. The one or more rails include two intermediary members attached to or integrally formed as part of the slide torsion plate and extending laterally along a top edge and a bottom edge of the slide torsion plate. The brackets are configured to form channels with a sidewall of the processing chamber and retain the slide torsion plate from moving away from the processing chamber. The cam followers are disposed in the channels. The slide torsion plate and the intermediary members slide via the cam followers and relative to the processing chamber and the brackets.

The slide and pivot assembly further includes: track rollers configured to attach to the processing chamber and including ‘V’-shaped grooves; and brackets configured to attach to the processing chamber and forming channels with a sidewall of the processing chamber. The brackets retain the slide torsion plate from moving away from the processing chamber. The one or more rails are attached to or integrally formed as part of the slide torsion plate and slide in the ‘V’-shaped grooves. The slide torsion plate slides via the one or more rails and the track rollers relative to the processing chamber.

In other features, the slide and pivot assembly further includes roller blocks. The roller blocks include: a first set of rollers; and a second set of rollers cross-connected relative to the first set of rollers. The one or more rails are attached to the slide torsion plate. The slide torsion plate slides via the first set of rollers and the second set of rollers relative to the roller blocks.

In other features, the one or more rails include two rails disposed on a top edge and a bottom edge of the slide torsion plate. Each of the two rails includes a ‘V’-shaped groove. The first set of rollers roll along first surfaces of the ‘V’-shaped grooves. The second set of rollers roll along second surfaces of the ‘V’-shaped grooves.

In other features, the one or more rails are attached to the slide torsion plate via fasteners. In other features, the one or more rails are integrally formed as part of the slide torsion plate.

In other features, the slide and pivot assembly further includes an end plate and bearing blocks configured to be mounted on the processing chamber. The slide torsion plate is ‘C’-shaped and attached to the end plate. The bearing blocks include the bearings. The one or more rails includes two rails mounted on the slide torsion plate and configured to ride on the bearings of the bearing blocks.

In other features, the slide and pivot assembly further includes slides configured to attach to the processing chamber. The one or more rails are telescopic rails attached to the slide torsion plate. The bearings are disposed between the one or more rails and the slides allowing the slide torsion plate to slide relative to the slides and the processing chamber.

In other features, the slide and pivot assembly further includes slides attached to the slide torsion plate. The one or more rails are telescopic rails configured to attach to the processing chamber. The bearings are disposed between the one or more rails and the slides allowing the slide torsion plate to slide relative to the telescopic rails and the processing chamber.

In other features, the slide and pivot assembly further includes slide assemblies with ‘V’-shaped grooved track rollers. The one or more rails are integrally formed as part of the slide torsion plate. The slide assemblies are configured to attach to the processing chamber. The one or more rails slide relative to the ‘V’-shaped grooved track rollers.

In other features, one of the slide assemblies includes a slide lock assembly configured to prevent the slide torsion plate from sliding relative to the processing chamber. In other features, at least one of the slide assemblies includes a block with a groove in which one of the one or more rails slides. The block functions as a support to retain the slide torsion plate.

In other features, a slide and pivot assembly for a process module bias assembly of a substrate processing system is provided. The slide and pivot assembly includes bearing blocks, rails, a bias mounting plate and a hinge assembly. The bearing blocks are configured to attach to a processing chamber and include bearings. The rails configured to slide relative to the bearing blocks via the bearings. The bias mounting plate is configured to hold a portion of a process module for processing a substrate. The hinge assembly attached to the rails and the bias mounting plate. The bias mounting plate and the hinge assembly are configured to slide via the rails and bearings in a lateral direction relative to the processing chamber. The bias mounting plate is configured to pivot relative to the rails while the slide and pivot assembly is in at least a partially pulled out state.

In other features, the rails include a first rail, a second rail and a third rail. The second rail is disposed below the first rail. The third rail is disposed below the second rail. In other features, the rails are cylindrically-shaped rails. In other features, the rails include web rails. Each of the web rails includes cylindrically-shaped top and bottom edges extending along and attached to a longitudinal member.

In other features, a tool is provided and includes: a wafer transfer module; a first row of stations on a first side of the wafer transfer module; and a second row of stations on a second side of the wafer transfer module. The wafer transfer module is configured to transfer substrates to and from the first row of stations and the second row of stations. Each station in the first row of stations and the second row of stations includes: a processing chamber; a slide and pivot assembly attached to the processing chamber; and a bias assembly attached to the slide and pivot assembly and a substrate support, and configured to be pulled out and pivoted away from the processing chamber via the slide and pivot assembly.

In other features, each of the slide and pivot assemblies is configured to transition from a closed state to pulled out and pivoted state to remove a corresponding one of the substrate supports from a corresponding one of the processing chambers and pivot the corresponding one of the substrate supports away from a corresponding one of the processing chambers.

In other features, the wafer transfer module includes a robot for transferring the substrates to and from some of the first row of stations and the second row of stations. In other features, the wafer transfer module is attached to an equipment front end module and load lock and transfers the substrates from the equipment front end module and load lock to the first row of stations and the second row of stations.

In other features, the robot is configured to transfer the substrates between a buffer and the some of the first row of stations and the second row of stations. In other features, each of the first row of stations and the second row of stations includes a vertical arrangement of a radio frequency generator and gas box, a top plate assembly, a corresponding one of the processing chambers, and a vacuum pump.

In other features, each of the slide and pivot assemblies includes: a slide torsion plate; one or more rails and bearings configured to attach to the slide torsion plate or corresponding one of the processing chambers; a bias mounting plate configured to hold a portion of a process module for processing one of the substrates; and a hinge assembly attached to the slide torsion plate and the bias mounting plate. The slide torsion plate, the bias mounting plate and the hinge assembly are configured to slide via the one or more rails and bearings in a lateral direction relative to the corresponding one of the processing chambers. The bias mounting plate is configured to pivot relative to the slide torsion plate while the slide and pivot assembly is in at least a partially pulled out state.

In other features, the hinge assembly of each of the slide and pivot assemblies includes: a first hinge member attached to a corresponding one of the slide torsion plates; a second hinge member attached to a corresponding one of the bias mounting plates and connected to pivot relative to the first hinge member. The corresponding one of the bias mounting plates and the second hinge member are configured to pivot relative to the corresponding one of the slide torsion plates and the first hinge member while the slide and pivot assembly is in at least a partially pulled out state.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a perspective view of portions of two tools including example slide and pivot assemblies in accordance with the present disclosure;

FIG. 2 is a top view of a portion of one of the tools of FIG. 1;

FIG. 3 is a side view of a portion of one of the tools of FIG. 1;

FIG. 4 is a top view of a substrate processing station including a slide and pivot assembly in accordance with the present disclosure;

FIG. 5 is a perspective view of a substrate processing system illustrating a slide and pivot assembly in a fully docked state in accordance with the present disclosure;

FIG. 6 is a perspective view of the substrate processing system of FIG. 5 illustrating the slide and pivot assembly in a fully undocked (or fully rotated) state in accordance with the present disclosure;

FIG. 7 is a top view of a process module bias assembly illustrating a fully pulled out and non-rotated (or non-pivoted) state in accordance with the present disclosure;

FIG. 8 is a top view of the process module bias assembly of FIG. 7 illustrating a pivot angle of rotation associated with the fully undocked state in accordance with the present disclosure;

FIG. 9 is a top view of a processing chamber and the process module bias assembly illustrating an interim pivot state;

FIG. 10 is a perspective view of a portion of the processing chamber and the process module bias assembly of FIG. 9 illustrating a slide lock locked for a fully docked state in accordance with the present disclosure;

FIG. 11 is a perspective view of a portion of the processing chamber and the process module bias assembly of FIG. 9 illustrating a slide lock locked for a fully pulled out state in accordance with the present disclosure;

FIG. 12 is a side perspective view of the slide and pivot assembly of FIG. 9 in accordance with the present disclosure;

FIG. 13 is a side perspective view of a slide torsion plate and an adjustable hinge assembly for the slide and pivot assembly of FIG. 9;

FIG. 14 is a side perspective view of a portion of the slide and pivot assembly of FIG. 9 including a slide torsion plate, guide rails, bearing blocks, pivot lock assembly, and the slide lock assembly;

FIG. 15 is a front cross-sectional view of the slide torsion plate, bearing blocks, and pivot lock assembly of FIGS. 9 and 14;

FIG. 16 is a side view of a slide lock assembly in accordance with the present disclosure;

FIG. 17 is a top sectional view of a pivot lock assembly in accordance with the present disclosure;

FIG. 18 is a perspective view of a jack screw assembly in accordance with the present disclosure;

FIG. 19 is a side sectional view of the jack screw assembly of FIG. 18;

FIG. 20 is a perspective view of a portion of the slide and pivot assembly of FIG. 9 including the slide torsion plate, a hinge assembly and a slide and pivot interlock mechanism in accordance with the present disclosure;

FIG. 21 is a bottom view of the slide and pivot interlock mechanism of FIG. 20;

FIG. 22 is an inner side view of a portion of the slide and pivot assembly of FIG. 20 illustrating an adjustable catch member while the corresponding hinge assembly is in a non-rotated state;

FIG. 23 is an inner side perspective view of a portion of the slide and pivot assembly of FIG. 9 illustrating a toggle stop bracket while the corresponding hinge assembly is in a rotated state;

FIG. 24 is a cross-sectional view of a bearing assembly for a hinge assembly of in accordance with the present disclosure;

FIG. 25 is a cross-sectional perspective view of the bearing assembly of FIG. 24 illustrating a tapered roller bearing with locknut and washer and a thrust bearing between hinge halves;

FIG. 26 is a front view of a slide and pivot assembly illustrating an example sag angle due to weight of the corresponding process module bias assembly;

FIG. 27 is a side cross-sectional view of an alignment pin and receiving bushing in accordance with the present disclosure;

FIG. 28 is a front perspective view of the processing chamber of FIG. 9 including alignment pins in accordance with the present disclosure;

FIG. 29 is a perspective view of another hinge assembly in accordance with the present disclosure;

FIG. 30 is a front view of the hinge assembly of FIG. 29;

FIG. 31 is a perspective view of a portion of another slide and pivot assembly in accordance with the present disclosure;

FIG. 32 is a perspective view of a portion of the slide and pivot assembly of FIG. 31 illustrating disengagement of a latch bar and adjustable catch in accordance with the present disclosure;

FIG. 33 is a perspective view of a portion of the slide and pivot assembly of FIG. 31 illustrating engagement of the latch bar and adjustable catch in accordance with the present disclosure;

FIG. 34 is a side view of a portion of the slide and pivot assembly of FIG. 31 illustrating a torsion spring in accordance with the present disclosure;

FIG. 35 is a bottom view of a portion of the slide and pivot assembly of FIG. 31 illustrating a latch bar in an engaged state in accordance with the present disclosure;

FIG. 36 is a perspective view of a portion of a hinge assembly of the slide and pivot assembly of FIG. 31 illustrating a non-rotated state with latch bar engaged in accordance with the present disclosure;

FIG. 37 is a perspective view of a portion of the hinge assembly of the slide and pivot assembly of FIG. 31 illustrating a pivoted state with latch bar disengaged in accordance with the present disclosure;

FIG. 38 is a top view of a portion of the hinge assembly of the slide and pivot assembly of FIG. 31 illustrating a non-rotated state with latch bar engaged in accordance with the present disclosure;

FIG. 39 is a top view of a portion of the hinge assembly of the slide and pivot assembly of FIG. 31 illustrating a pivoted state with latch bar disengaged in accordance with the present disclosure;

FIG. 40 is a side cross-sectional view of another jack screw assembly illustrating a jack screw block in an ON (IN) position and a jack screw in a fastened state in accordance with the present disclosure;

FIG. 41 is a side cross-sectional view of the jack screw assembly of FIG. 40 illustrating the jack screw block in an OFF (OUT) position;

FIG. 42 is a side cross-sectional view of the jack screw assembly of FIG. 40 illustrating the jack screw block in the ON position and the jack screw pulled out;

FIG. 43 is a perspective view of the jack screw of FIG. 40 and corresponding components;

FIG. 44 is a front perspective view of a jack screw block including a jack screw wear component in accordance with the present disclosure;

FIG. 45 is a back perspective view of the jack screw block of FIG. 44;

FIG. 46 is a side cross-sectional view of a jack screw assembly including the jack screw block of FIG. 44 in accordance with the present disclosure;

FIG. 47 is a front perspective view of a processing chamber including a portion of another slide and pivot assembly including cam followers in accordance with the present disclosure;

FIG. 48 is a end view of the portion of the slide and pivot assembly of FIG. 47;

FIG. 49 is a side perspective view of a processing chamber including a portion of another slide and pivot assembly including torsion plate with tracks for ‘V’-grooved cam followers in accordance with the present disclosure;

FIG. 50 is a end view of the portion of the slide and pivot assembly of FIG. 49;

FIG. 51 is a perspective view of a processing chamber including a slide and pivot assembly illustrating directions of torsional and vertical stiffness of a torsion plate in accordance with the present disclosure;

FIG. 52 is a end view of a portion of the slide and pivot assembly of FIG. 51 illustrating space constraints in accordance with the present disclosure;

FIG. 53 is a side perspective view of a processing chamber including another slide and pivot assembly with cylindrical-shaped rails and corresponding rail guides in accordance with the present disclosure;

FIG. 54 is a perspective view of a portion of another slide and pivot assembly including web rails and corresponding rail guides in accordance with the present disclosure;

FIG. 55 is a perspective view of a portion of another slide and pivot assembly including a torsion plate with top and bottom edge roller guides and corresponding roller blocks in accordance with the present disclosure;

FIG. 56 is another perspective view of one of the edge roller guides and corresponding roller block of FIG. 55;

FIG. 57 is a side view of the edge roller guide and the roller block of FIG. 56;

FIG. 58 is a side view of a torsion plate with an integrally formed edge roller guide and a roller block in accordance with the present disclosure;

FIG. 59 is a perspective view of a processing chamber including another slide and pivot assembly including a ‘C’-shaped torsion plate with an end cap and support rails sliding relative to open bearing blocks in accordance with the present disclosure;

FIG. 60 is a side perspective view of the support rails and open bearing blocks of FIG. 59;

FIG. 61 is an inner side perspective view of a portion of another slide and pivot assembly including telescopic rails and slides in accordance with the present disclosure;

FIG. 62 is a side view of the portion of the slide and pivot assembly of FIG. 61; and

FIG. 63 is a side perspective view of a portion of another slide and pivot assembly including a torsion plate with top and bottom edge rails for slide assemblies with ‘V’-shaped grooved track rollers.

In the drawings, reference numbers may be reused to identify similar and/or identical elements.

### DETAILED DESCRIPTION

A semiconductor fabrication (fab) room may include multiple tools each including multiple substrate processing stations (hereinafter referred to as “stations”). Each of the stations can be configured to perform, for example, a conductor etch process, a dielectric etch process or other substrate treatment. Space within a fab room is limited and thus the amount of space available to access each of the tools to perform, for example, service and/or maintenance on a station is limited. The stations of the tools may be arranged in a star-shaped pattern or a linear pattern. When in the star-shaped pattern, the stations are disposed around a centrally located wafer transfer module with a robot, which moves substrates from a load lock chamber to each of the substrate processing stations and back. Although this arrangement of stations provides some access space between stations, density of stations is less than the density of stations in the linear pattern. When in the linear pattern, the stations are disposed side-by-side to form two rows of stations; one row on each side of a wafer transfer module, which may operate at atmosphere or vacuum. Although the linear-shaped arrangement allows for more stations to be disposed within a dedicated space, the linear-shaped arrangement provides restricted access to sides of the stations.

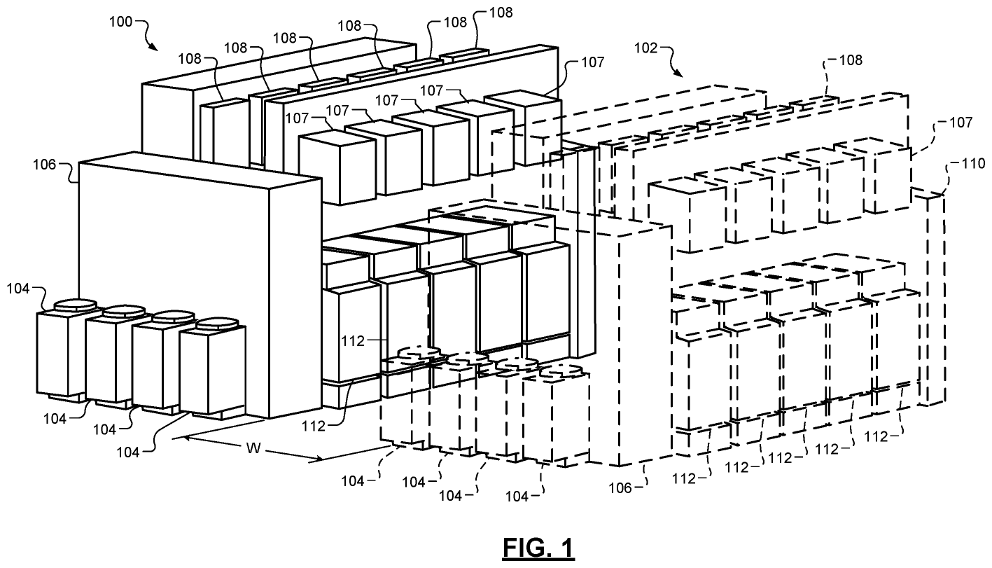

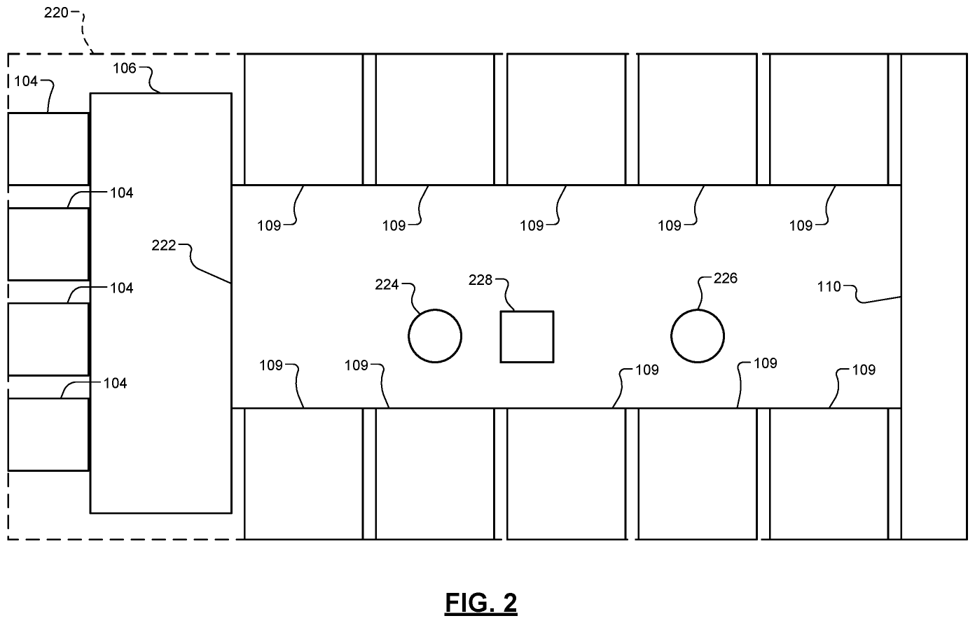

FIGS. 1 and 2 show portions of two tools 100, 102 (one in solid lines at 100 and the other in dashed lines at 102) disposed side-by-side in a fab room. Each of tools includes two rows of stations (one row is shown for each of the tools). The stations are located adjacent to a wafer transfer module (not depicted in FIG. 1 for clarity). There is limited space between the tools 100, 102. As an example, a width W of an aisle between the tools 100, 102 may be small. This provides a minimal amount of space between the tools 100, 102 to open processing chambers of the stations and obtain access to process modules and interiors of corresponding processing chambers.

The examples set forth herein include slide and pivot assemblies for stations allowing process module bias assemblies of stations to be pulled out and pivoted away from corresponding processing chambers and to allow service or maintenance to be performed in the aisle. The slide and pivot assemblies are configured to repeatedly pull out from a fully docked state to a fully undocked state and accurately return the process module bias assemblies to same fully docked locations as when previously docked. As an example, the slide and pivot assemblies are able to return the process module bias assemblies to locations within ±25 micrometers (μm, referred to as microns) of the last fully docked state. The slide and pivot assemblies are configured to handle and compensate for the heavy loads of the process module bias assemblies. An example overall weight of a process module bias assembly and corresponding slide and pivot assembly is 300 kilograms (kg). The slide and pivot assemblies provide ease of use and ease of assembly.

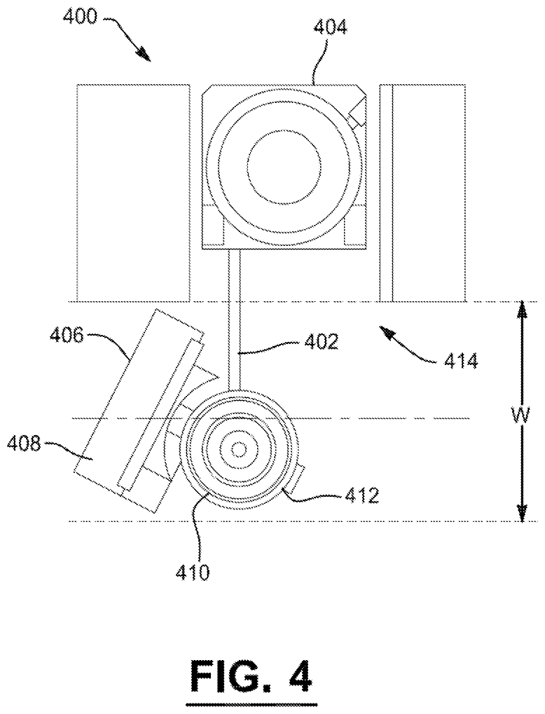

The tools 100, 102 include: front opening unified pods (FOUPs) 104; an equipment front end module (EFEM) and load lock 106; stations with radio frequency generators 107 and gas boxes 108; and a power lock out and tag out system 110. The stations further include process module bias assemblies 112, which include respective slide and pivot assemblies, examples of which and corresponding portions thereof are shown in FIGS. 4-30.

Each of the stations alone or in combination may be referred to as a substrate processing system. Each of the stations may be used to etch substrates using, for example, radio frequency (RF) plasma. Each station includes a processing chamber, such as an inductive coupled plasma (ICP) chamber or a conductive coupled plasma (CCP) chamber. The stations may, for example, perform conductive etch or dielectric etch processes.

FIG. 2 shows a portion of one of the tools 100, 102 of FIG. 1. The tool includes the FOUPs 104, the EFEM and load lock 106, the stations 109, and the power lock out and tag out system 110. The tool has an overall footprint 220. The tool further includes a wafer transfer module 222 for transferring substrates to and from the stations 109. The wafer transfer module 222 may include robots 224, 226 and a buffer 228 for temporary storage of wafers. The robots 224, 226 transfer wafers to and from the stations 109 and the buffer 228. Although positioned between robot 224 and robot 226 in FIG. 2, buffer 228 may be positioned anywhere in wafer transfer module 222. In other embodiments, the buffer 228 may be positioned outside wafer transfer module 222 (e.g., coupled to stations 109 or load lock 106).

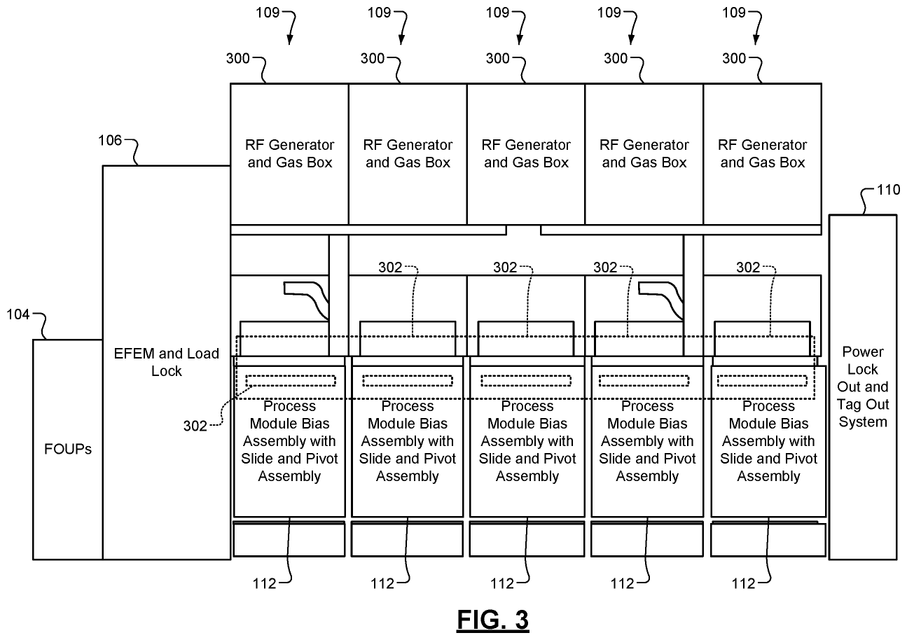

FIG. 3 shows a portion of one of the tools 100, 102 of FIG. 1. The tool includes the FOUPs 104, the EFEM and load lock 106, the stations 109, and the power lock out and tag out system 110. The stations include the RF generators and gas boxes (collectively referred designated 300) and the process module bias assemblies with slide and pivot assemblies 112. The RF generators may provide RF power to electrodes in substrate supports of the stations. The gas boxes supply gases to processing chambers of the stations. The wafer transfer module 222 is also shown.

Substrates scheduled to be loaded and processed are stored in the FOUP 104. The substrates are transferred from the FOUP 104 to the stations 109 via the EFEM and load lock 106 via respective loading ports 302. The RF generators and gas boxes 300 are arranged above the stations 109 and supply RF power and process gases to process modules of the stations 109.

FIG. 4 shows a substrate processing station 400 (including a slide and pivot assembly 402), which is an example of one of the stations 109 of FIGS. 2-3. The slide and pivot assembly 402 is connected to a processing chamber 404 and a process module bias assembly 406. The slide and pivot assembly 402 allows the process module bias assembly 406 to be pulled out away from the processing chamber 404 and pivoted up to a predetermined angle relative to a front face of the processing chamber 404. The process module bias assembly 406 includes a housing 408, a portion 410 of a process module including a process bias bowl 412. The process module may include, in addition to the process bias bowl 412, an electrostatic chuck and/or other substrate support, and a top plate assembly, examples of which are shown in FIG. 6.

The example width W of an aisle between the station 400 and an opposing station is shown to illustrate that the process module bias assembly 406 is able to be pulled out and pivoted within the aisle. This provides a clear open space 414 on a right side of the slide and pivot assembly 402 for a technician to access the process bias bowl 412 and an interior of the processing chamber 404 for service and maintenance purposes including wet cleaning. The process bias bowl 412 and an interior of the processing chamber 404 are accessed from a right side of the process module bias assembly 406 without interference. For example, no slides, rails and/or other components are in the open space 414 and/or interfere with a technician accessing the interior of processing chamber 404. Although the process module and bias assembly 406 is shown pivoting to the left, the slide and pivot assembly may be configured and mounted on the right side of the processing chamber such that the process module and bias assembly pull out and pivot to the right relative to the processing chamber.

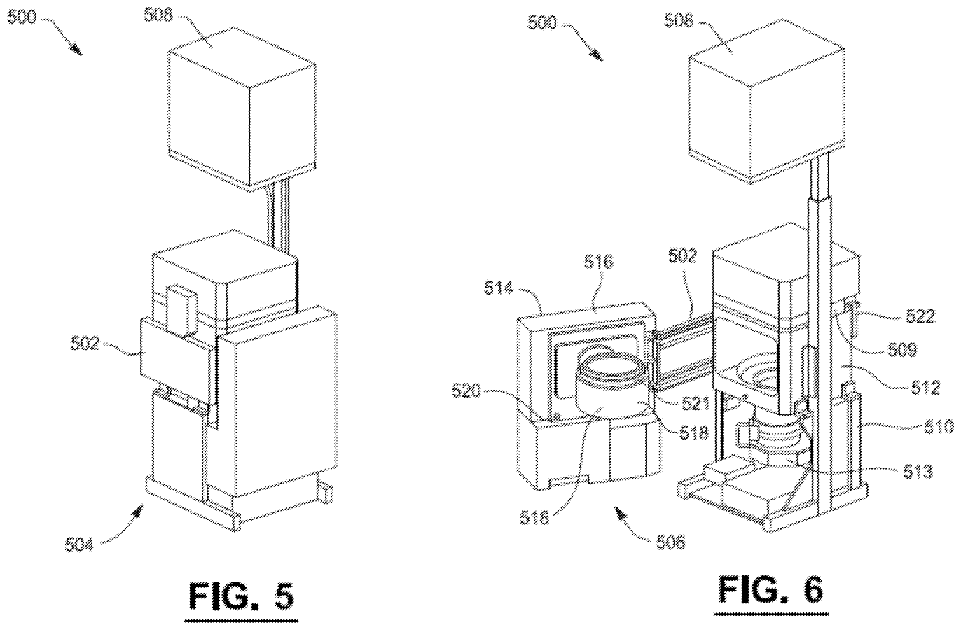

FIGS. 5 and 6 show a substrate processing system 500 illustrating a slide and pivot assembly 502 in a fully docked state 504 and in a fully undocked state 506. The substrate processing system 500 includes a vertical arrangement of a RF generator and gas box 508, a top plate assembly 509, a processing chamber 512, and a turbo pump 513 for evacuating the processing chamber 512. The processing chamber 512 sits on a stand 510 and includes a process module bias assembly 514. The process module bias assembly 514 includes a housing 516 and a process module bias bowl 518 attached to a bias mounting plate 520 of the slide and pivot assembly 502. A portion 521 of a substrate support, such as an electrostatic chuck (ESC), is shown coupled to the process bias bowl 518. The top plate assembly 509 is shown on the processing chamber 512. The process module bias assembly 514 includes circuits for supplying RF and/or bias power to electrodes of the substrate support and/or power to heater elements of the substrate support and may include coolant channels for supplying coolant to cool the substrate support. During operation, a substrate is received from a backside of the processing chamber 512 via an access port 522 and arranged on the substrate support.

The slide and pivot assembly 502 is attached to a wall of the processing chamber 512 and is configured to hold the weight of the process module bias assembly 514, which includes the weight of the slide and pivot assembly for a total assembly mass of, for example 300 kg. The slide and pivot assembly 502 is configured to handle more than a predetermined minimum number of undocking, redocking, opening and closing cycles per year (e.g., 100 cycles per year) for a predetermined number of minimum years (e.g., 10 years). The slide and pivot assembly is configured to provide a repeatable closed and fully docked position. The slide and pivot assembly is configured to be within, for example, 25 μm of an initial closed and fully docked position each time the corresponding processing chamber is opened and then returned to a closed state. This allows for repeatable undocking and redocking without need for recalibration of parameters associated with a location of the substrate support.

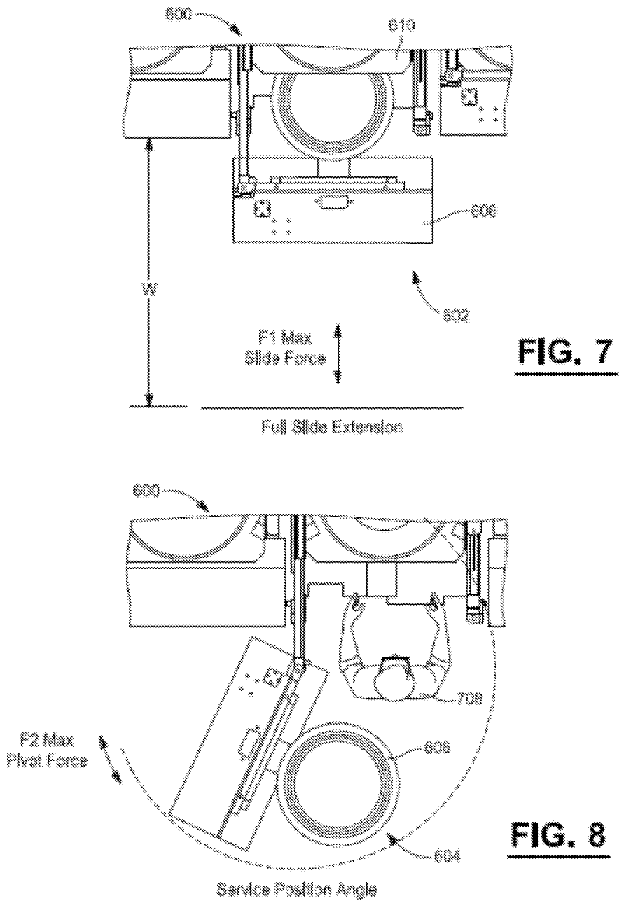

FIGS. 7 and 8 show a process module bias assembly 600 illustrating a fully pulled out and non-rotated state 602 and pivot angle of rotation associated with the fully undocked state 604. The fully pulled out and non-rotated state 602 is an interim state between the fully docked and fully undocked states. The fully undocked state 604 refers to when the process module bias assembly 600 is fully rotated, such that the housing 606 and process module bias bowl 608 are fully pivoted away from the processing chamber 610. While in a fully undocked state, a technician 708 is able to access the interior of the processing chamber 610 as shown while in a standing and/or kneeling position. The process module bias assembly 600 may have a predetermined maximum slide force F1 that may have a unit of measure of pound-force (lbf) and a predetermined maximum pivot (or rotational) force F2, which may also be measured unit of measure of lbf.

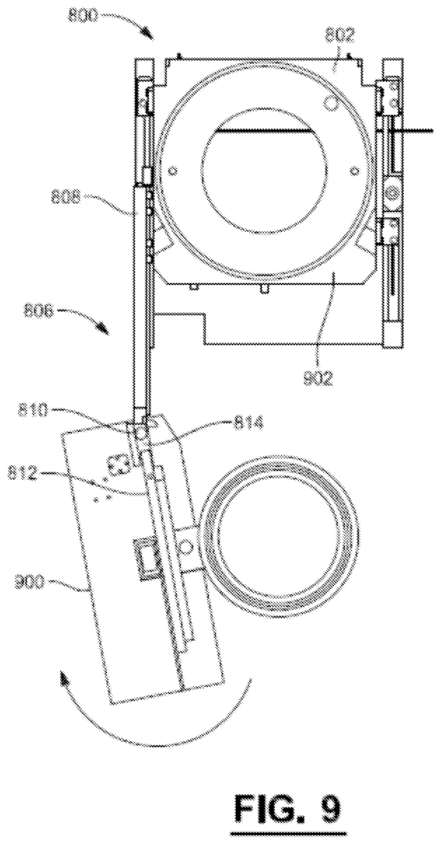

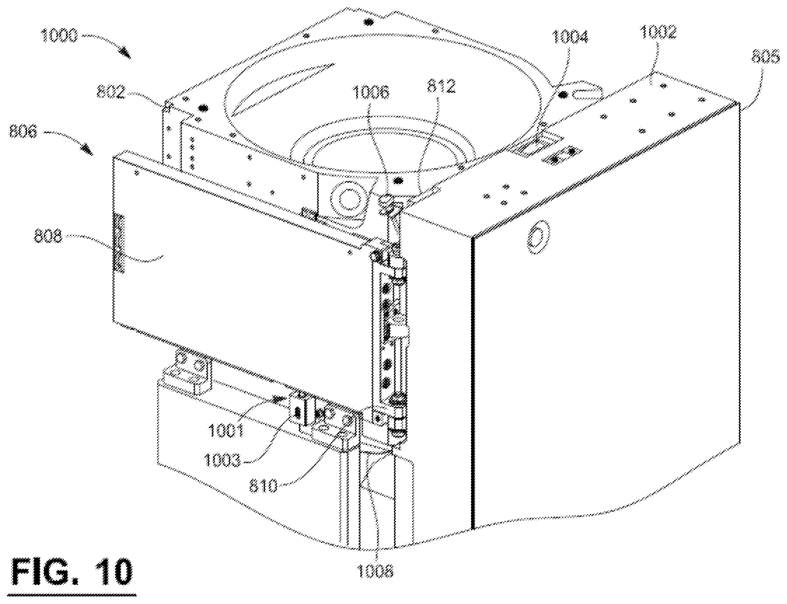

FIG. 9 shows a portion 800 of a processing chamber 802 including a process module bias assembly 805 (shown in FIG. 10) having a slide and pivot assembly 806. The processing chamber 802 and the slide and pivot assembly 800 may be implemented in any of the above-stated stations and have similar aspects as any of the above-stated processing chambers and slide and pivot assemblies. The slide and pivot assembly 806 includes a slide torsion plate 808, a hinge assembly 810 and a bias mounting plate 812. A pivot lock assembly 814 is shown attached to the hinge assembly 810. The pivot lock assembly 814 as further described below locks the bias mounting plate 812 in a non-pivoted state and in a fully pivoted state. The bias mounting plate 812 has bias bowl mounting features.

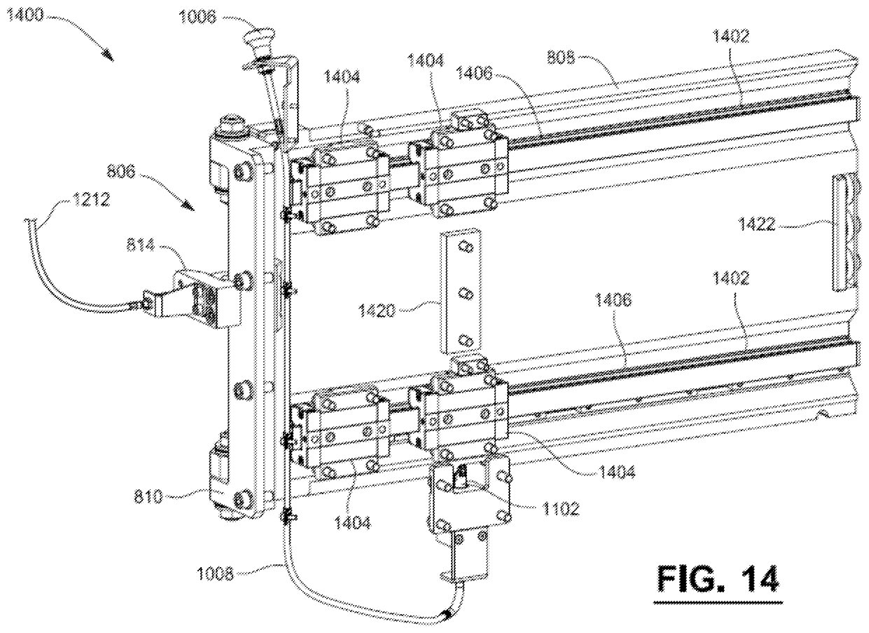

The slide and pivot assembly 806 is shown in an interim pivot state between the non-pivoted state and the fully pivoted state. The slide pivot assembly 806 is shown at an 80° pivot angle relative to the front sidewall 902 of the processing chamber 802. This may be a worse case bearing load position for bearings of bearing blocks of the slide and pivot assembly 806. The bearing blocks are shown in FIG. 14. The slide torsion plate 808 handles the offset load and works in torsion to support the load. The slide torsion plate 808 provides stiffness to support the cantilevered load of the bias assembly weight, and limits deflections both in the vertical and twist directions. The resulting structure is more space efficient than a design using larger rails without a torsion plate, thus allowing for shorter spacing between processing chambers, and resulting in a smaller system footprint.

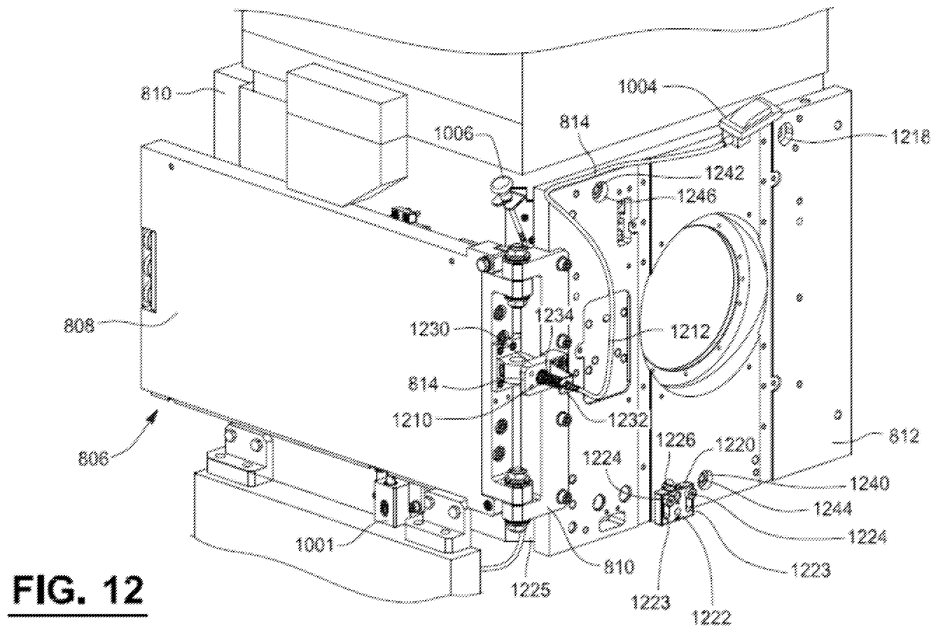

FIG. 10 shows a portion 1000 of a processing chamber 802 and the corresponding process module bias assembly 805 including the slide and pivot assembly 806 of FIG. 9. The process module bias assembly 805 includes a housing 1002. A pivot lock actuator 1004 allows the housing 1002 along with the bias mounting plate 812 to be secured to processing chamber 802, or released and pivoted away from the processing chamber 802. The bias mounting plate 812 is attached to a backside of the housing 1002. The pivot lock actuator 1004 may be a “pull-tab” that pulls a cable in a cable assembly (shown in FIG. 12) to release a pivot lock plunger of the pivot lock assembly 814. The slide and pivot assembly 806 includes a slide lock assembly 1001 with a slide lock 1003 shown in a locked state while the slide and pivot assembly 806 is in a fully docked state. A slide lock actuator 1006 allows the housing 1002 along with the bias mounting plate 812 to slide in a horizontal linear manner away from the processing chamber 802. The slide lock actuator 1006 may be a “pull-knob” that pulls a cable in a cable assembly 1008 to release a slide lock plunger of the slide lock assembly 1001. Alternatively, the slide lock plunger could be actuated by electric or pneumatic control. The pivot lock plunger of the pivot lock assembly 814 may also alternatively be actuated by electric or pneumatic control.

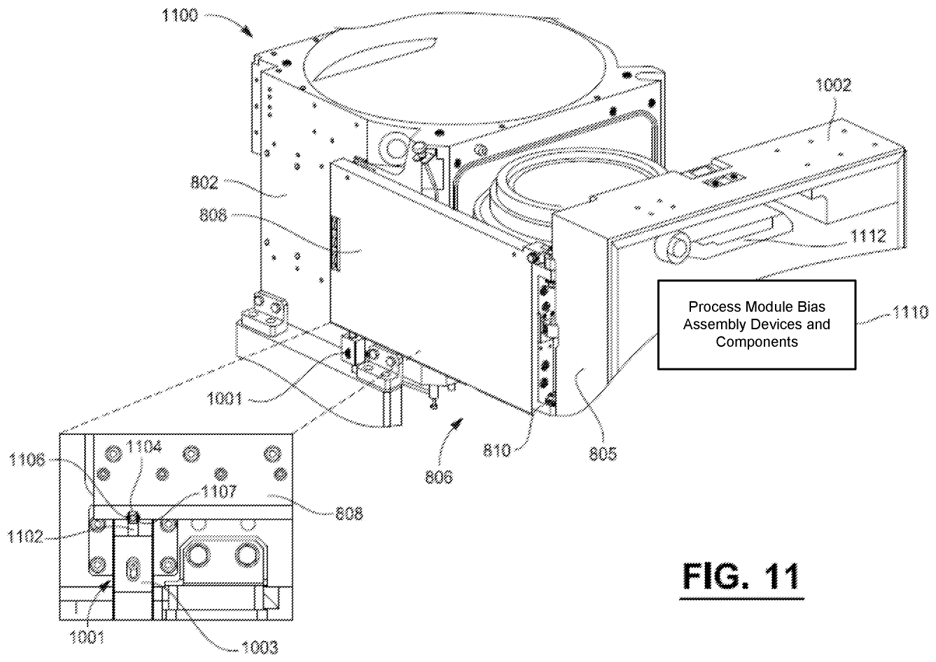

FIG. 11 shows a portion 1100 of the processing chamber 802 and the corresponding process module bias assembly 805 including the slide and pivot assembly 806 illustrating the slide lock 1003 locked in a fully pulled out state. The slide and pivot assembly 806 includes the slide torsion plate 808 and the hinge assembly 810. The slide lock 1003 includes a plunger 1102 and wheel 1104 that is pushed into notches (one notch 1106 is shown) in the slide torsion plate 808 for different slide lock states of the slide and pivot assembly 806. The wheel 1104 spins on a pin 1107. Process module bias assembly devices and components 1110 are disposed in the housing 1002 and may include RF sources, bias voltage sources, power sources, power cables, conductive lines, coolant lines, gas lines, etc. This may include a pull handle 1112 for pulling out the process module bias assembly 805.

FIG. 12 shows the slide and pivot assembly 806 including the slide torsion plate 808, the hinge assembly 810 and the bias mounting plate 812, but not including housing 1002. The hinge assembly 810 is released from locked states by the pivot lock actuator 1004 of the pivot lock assembly 814. The pivot lock actuator 1004 is connected to a pivot lock plunger 1210 via a cable of a cable assembly 1212.

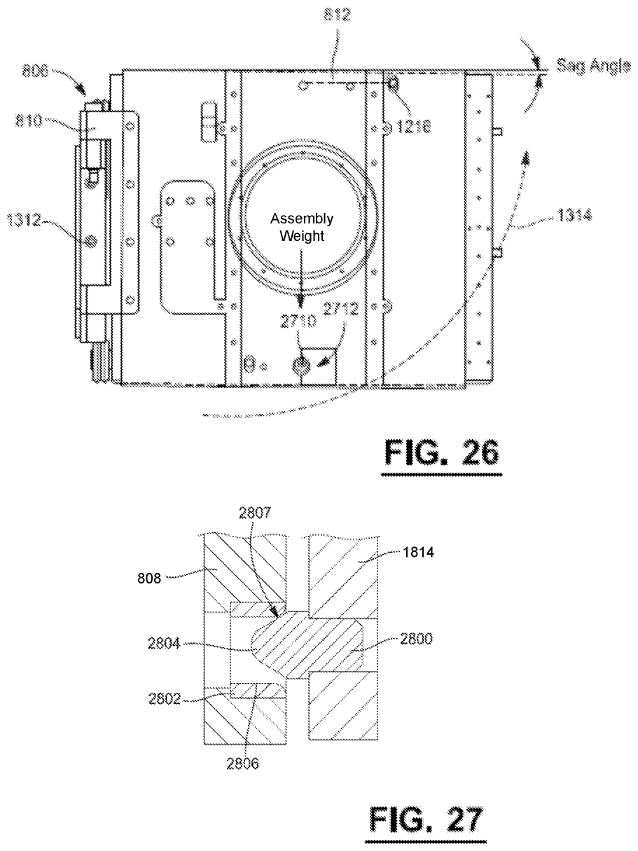

The bias mounting plate 812 is fastened to the front of the processing chamber 802 via one or more closure fasteners (e.g., bolts or screws) 1216 (shown in FIG. 26), which extends through one or more slots or holes 1218 in the bias mounting plate 812. The closure fasteners 1216 are attached after the slide and pivot assembly 806 is returned to a closed fully retracted (or fully docked) state.

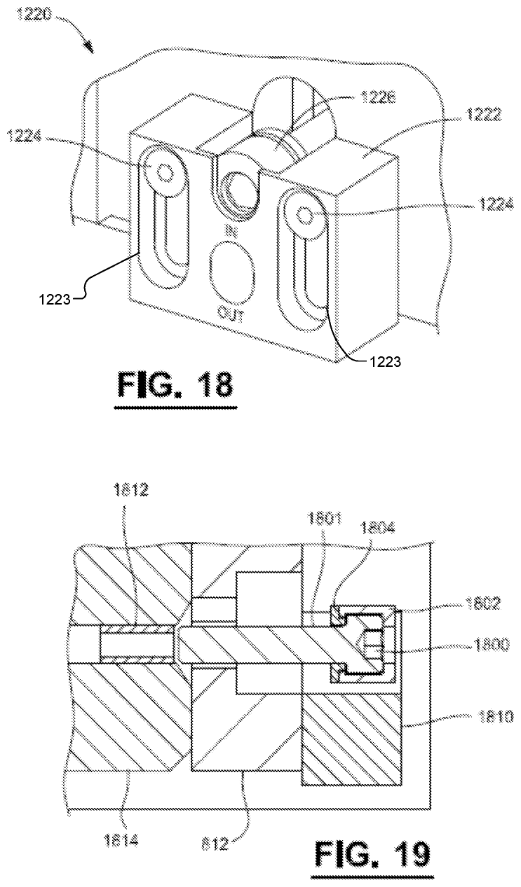

The slide and pivot assembly 806 may include a jack screw assembly 1220 including a jack screw block 1222, block fasteners 1224, and a jack screw 1226. Elements of the jack screw assembly 1220 are also shown in FIGS. 18-19. The jack screw block 1222 includes slots 1223 and slides on the block fasteners 1224 between an IN position and an OUT position. In some embodiments, the IN position is the default position. The jack screw block 1222 is shown in the IN position in FIG. 18. The block fasteners 1224 are shoulder screws, which may not clamp down the jack screw block 1222. In an embodiment, the jack screw block 1222 is free to fall under its own weight at all times. due to the weight of the jack screw block 1222. The jack screw 1226 extends through the bias mounting plate 812 and is fastened to a front wall 1225 of the processing chamber 802. While the jack screw block 1222 is in the IN position, the jack screw 1226 is able to be fastened to (or screwed into) the wall 1225 of the processing chamber 802. While in the OUT position, the jack screw 1226 is able to be CCW rotated (or partially unscrewed) to move out from the front wall 1225 and push pressure on the jack screw block 1222 to disengage one or more alignment pins, such as alignment pin 1244.

The pivot lock assembly 814 includes a block 1230, which is attached to the hinge assembly 810, the plunger 1210, a bracket 1232, and a spring 1234. The bracket 1232 holds the cable assembly 1212 for the plunger 1210 in place relative to the block 1230. A portion of the pivot lock assembly 814 is shown in FIG. 17.

The bias mounting plate 812 may include one or more holes for alignment pins. Two holes 1240, 1246 and the alignment pins 1242, 1244 are shown. An example of an alignment pin is shown in FIG. 27. The alignment pins 1242, 1244 are used to align the bias mounting plate 812 relative to the processing chamber 802 when docking the slide and pivot assembly 806. The alignment pins 1242, 1244 may be mounted on the processing chamber 802 and corresponding bushings may be mounted on the bias mounting plate 812. In one embodiment, the alignment pins 1242, 1244 are mounted on the bias mounting plate 812 and the corresponding bushings are mounted on the processing chamber 802. The jack screw 1226 may be used to move the bias mounting plate 812 ON and OFF of the alignment pins 1242, 1244. The jack screw 1226 may be tightened to, for example, insert ends of the alignment pins 1242, 1244 in the corresponding bushings in the bias mounting plate 812. The jack screw may not be torqued down, but rather simply used to engage alignment pins with corresponding bushings. The above-stated closure fasteners are used to close a gap between the bias mounting plate 812 and the processing chamber 802 after the alignment pins are inserted at least partially into the bushings via the jack screw 1226. Operation of the jack screw assembly 1220 is further described below with respect to FIGS. 18-19.

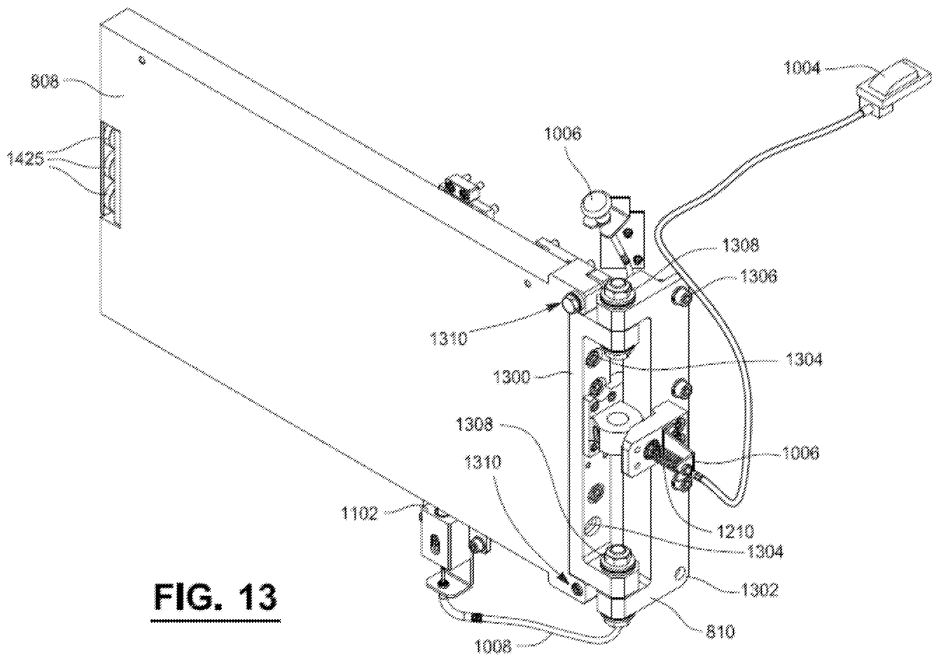

FIG. 13 shows the slide torsion plate 808 and an adjustable hinge assembly 810 for the slide and pivot assembly 806 of FIG. 9. The slide and pivot assembly 806 includes the slide torsion plate 808 and the hinge assembly 810. The slide lock actuator 1006 actuates the slide lock plunger 1102. The pivot lock actuator 1004 releases the plunger 1210 of the pivot lock assembly 814.

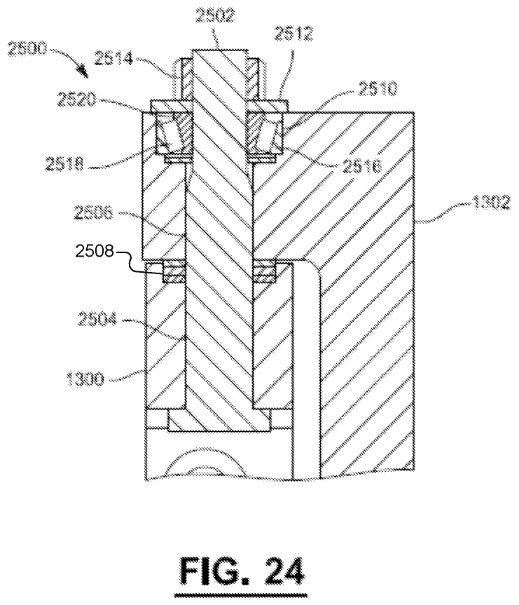

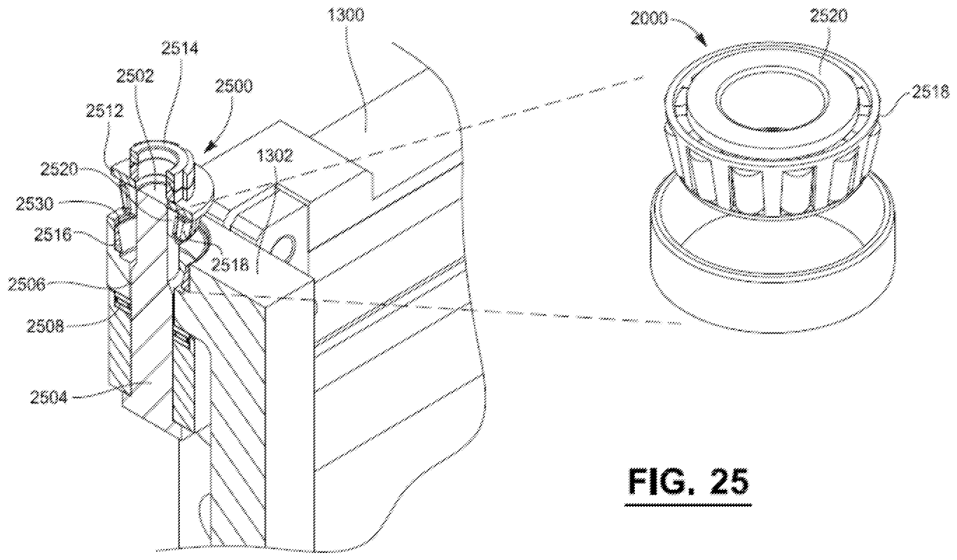

The hinge assembly 810 includes a slide torsion plate member 1300 and a bias mounting plate member 1302. The members 1300, 1302 (also referred to as hinge members) are “U-shaped”. The slide torsion plate member 1300 is connected to a front edge of the slide torsion plate 808 via fasteners (e.g., bolts or screws) 1304, and pivots on an alignment pin that is fixed to the torsion plate. The bias mounting plate member 1302 is attached to one end of the bias mounting plate 812 (shown in FIG. 12) via fasteners (e.g., bolts or screws) 1306 (one of which is not shown). The bias mounting plate member 1302 is attached and pivots relative to the slide torsion plate member 1300 via fasteners, such as central pivot members and/or fasteners 1308; other central pivot members are shown in FIGS. 24-25. A tilt angle of the hinge assembly 810 relative to the slide torsion plate 808 may be adjusted via fasteners (e.g., bolts or screws) 1310 (may be referred to as hinge adjustment fasteners). The tilt angle may be adjusted to compensate for sag due to the weight of the process module biasing assembly and slide and pivot assembly 806. An example sag angle is shown in FIG. 26. The bias mounting plate 812 may rotate clockwise due to the weight the process module biasing assembly and slide and pivot assembly 806 when pulled out away from the processing chamber 802. This twists the slide torsion plate 808. The fasteners 1310 may be turned in or out to rotate the bias mounting plate 812 in a CCW manner relative to a pivot point (represented by pivot point 1312 and CCW rotation arrow 1314 in FIG. 26) to compensate for the clockwise sag.

Referring now to FIGS. 12 and 14, which shows a portion 1400 of the slide torsion plate 808, a guide rail system including guide rails 1402 and bearing blocks 1404, the slide and pivot assembly 806, the pivot lock assembly 814, and the slide lock assembly 1001. The guide rails 1402 are attached to an inner side of the slide torsion plate 808. In an embodiment, the guide rails 1402 are implemented as profile ball rails. The pivot lock assembly 814 includes the pivot plunger 1210, the cable assembly 1212 and pivot lock actuator 1004. The slide lock assembly 1001 includes the slide plunger 1102, the cable assembly 1008 and slide lock actuator 1006. The bearing blocks 1404 include bearings (e.g., ball bearings) that ride in grooves 1406 of the guide rails 1402. The grooves are on both top and bottom sides of the guide rails 1402. The bearing blocks 1404 are fastened to a sidewall of a processing chamber (e.g., the processing chamber 802 of FIG. 9) via fasteners that extend through holes in the bearing blocks 1404. When actuated, the slide torsion plate 808 and guide rails 1402 are moved relative to the bearing blocks 1404.

The guide rail system has high load capacity, low friction and is able to handle a large amount of weight. The load range of the guide rail system is the same for both pulling out and retracting the slide torsion plate 808. Although the rails 1402 are shown as being mounted on the slide torsion plate 808 and the bearing blocks 1404 are shown as being mounted on a processing chamber wall, the slide torsion plate 808 may be mounted on the processing chamber wall and the bearing blocks 1404 may be mounted on the slide torsion plate 808. Mounting the bearing blocks 1404 on the processing chamber wall is done for decreasing sag, because the distances from the bearing blocks 1404 to the load center of mass decrease as the slide and pivot assembly is pushed in and closed, resulting in a shorter lever arm and reduced sag effect.

A slide stop block 1420 may be attached to the sidewall of the processing chamber 802 and limit movement of the slide torsion plate 808 along the guide rails 1402. A corresponding stopping member 1422 may be fastened to the slide torsion plate 808 and be against the slide stop block 1420 depending on the state of the slide and pivot assembly 806. The slide stop block 1420 may be in contact with the stopping member 1422 when in, for example, a fully pulled out (or open) state. An additional slide stop block and an additional stopping member may be provided for the fully docked (or closed) state. The slide stop blocks 1420 and stopping member 1422 may include dampers. Example dampers are shown as round disks 1425 in FIG. 13. Other dampers may be utilized.

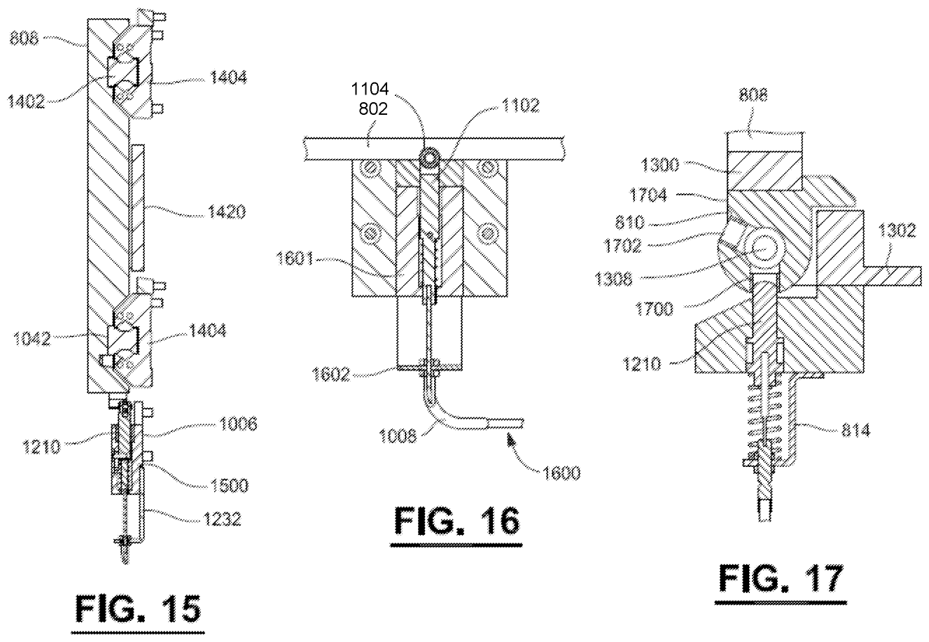

FIG. 15 shows the slide torsion plate 808, guide rails 1402, bearing blocks 1404, and slide lock assembly 1001 of FIG. 9-14. The guide rails 1402 are attached to the inside of the slide torsion plate 808. The bearing blocks 1404 ride on the guide rails 1402. The slide lock assembly 1001 includes the plunger 1210 and the bracket 1232, as well as a plunger housing 1500.

FIG. 16 shows a slide lock assembly 1600, which is attached to the processing chamber 802 and is an example of the slide lock assembly 1001 of FIG. 11. The slide lock assembly 1600 includes a slide lock housing 1601, the plunger 1102 and wheel 1104 that extends into notches in the slide torsion plate 808. A bracket 1602 is attached to the housing 1601 and holds the cable assembly 1008 relative to the housing 1601.

FIG. 17 shows the pivot lock assembly 814, which is attached to the bias mounting plate member 1302 of the hinge assembly 810. The hinge assembly 810 also includes the slide torsion plate member 1300, which is attached to the slide torsion plate 808. The hinge assembly 810 includes the fastener 1308, or other central pivot member, such as a pivot shaft or pin. Two locking positions for the plunger 1210 are shown and represented by channels 1700, 1702 in a pivot block 1704 attached to the slide torsion plate member 1300. The plunger 1210 is shown in the channel 1700, which is associated with the non-rotated state. The plunger 1210 may be pulled out of the channel 1700 and the bias mounting plate member 1302 may be rotated clockwise (CW) about the fastener 1308 and the plunger 1210 may then extend into the channel 1702. The channel 1702 is associated with the open (or fully rotated) position. The bias mounting plate member 1302 pivots to a fully open position at which the pivot lock plunger 1210 engages the channel 1702, referred to as a service position. The pivot lock plunger may be actuated by a pull cable (as shown in FIG. 13), or by electric or pneumatic control.

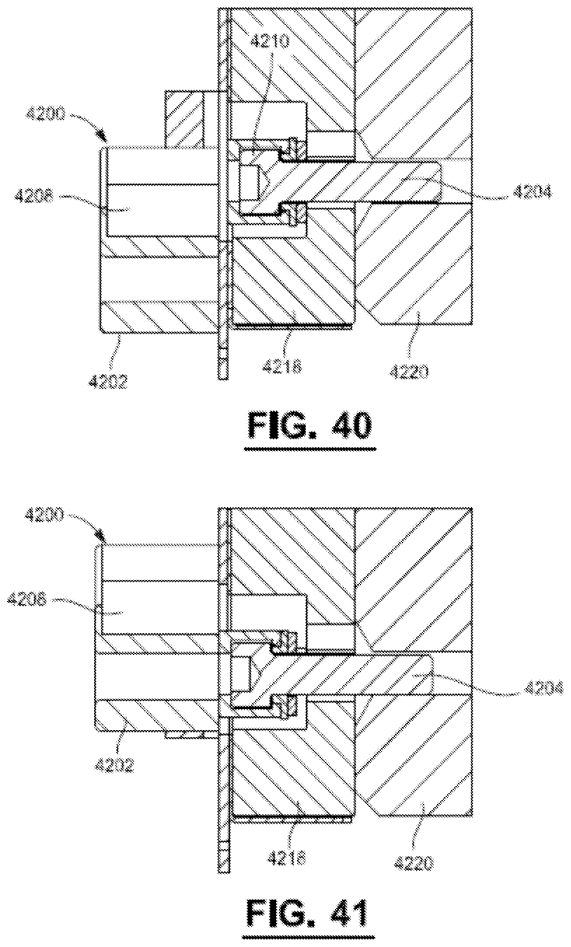

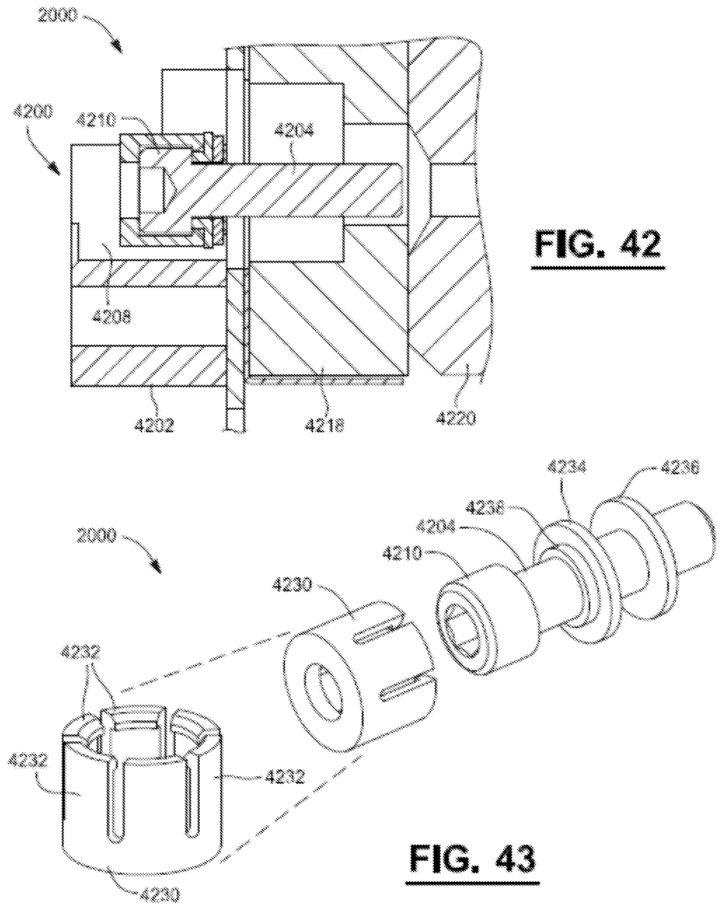

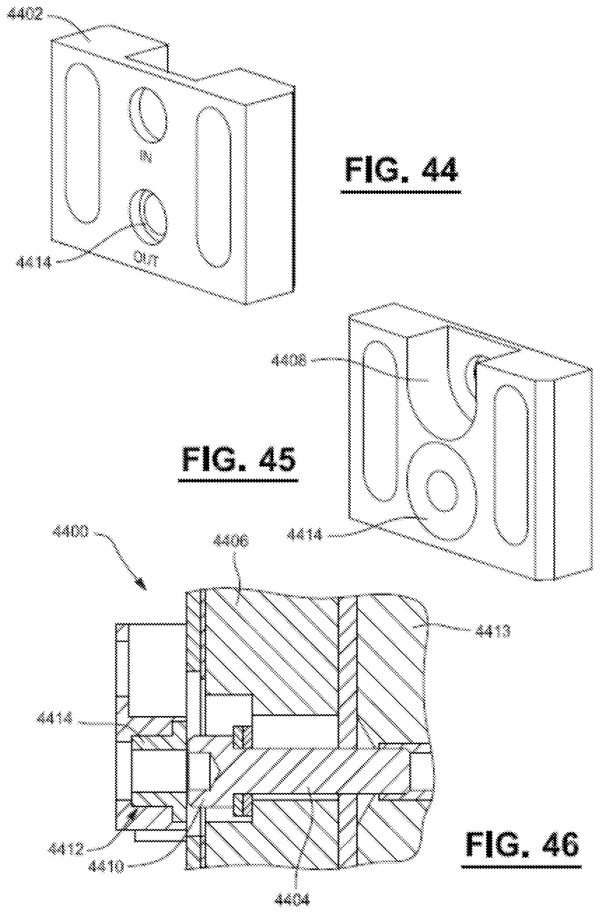

FIGS. 18-19 show the jack screw assembly 1220 including the jack screw block 1222, block fasteners 1224, and jack screw 1226. The jack screw block 1222 includes the slots 1223 and slides on the block fasteners 1224 between the IN and OUT positions. The IN and OUT positions correspond respectively to (i) the jack screw 1226 extending through the bias mounting plate 812 and fastening to the processing chamber 802, and (ii) the jack screw 1226 being used as a jack to release the bias mounting plate 812 from the processing chamber 802. While in the IN position, the head of the jack screw 1226 is able to extend into the jack screw block 1222 further than when in the OUT position. The jack screw 1226 includes a screw head 1800, a stem 1801, a screw head wear cap 1802 and a washer 1804. The jack screw block 1222 includes a stopper 1810 for the OUT position. The screw head wear cap 1802 is pressed against the stopper 1810 when the jack screw block 1222 is in the out position and the jack screw 1226 is being used to release the alignment pins from the corresponding bushings as described above. The stopper 1810 is a solid integral portion of the jack screw block 1222 that prevents the head 1800 of the jack screw 1226 from being moved into the jack screw block 1222. The stem 1801 may be threaded and be screwed into a threaded bushing 1812 inserted in the processing chamber wall 1814. Another jack screw assembly example is further shown in FIGS. 44-46. In an alternative embodiment, the screw head wear cap 1802 is not included and instead a wear element is inserted in the block OUT position covering a screw head contact area (i.e. stopper area) of the jack screw block 1222. In yet another alternative embodiment, the screw head wear cap 1802 is not included and the jack screw block 1222 is formed of a low friction low wear material. A similar example is shown in FIGS. 40-43. This embodiment utilizes a self-retaining wear cap with stepped washer, both of a low friction and low wear material.

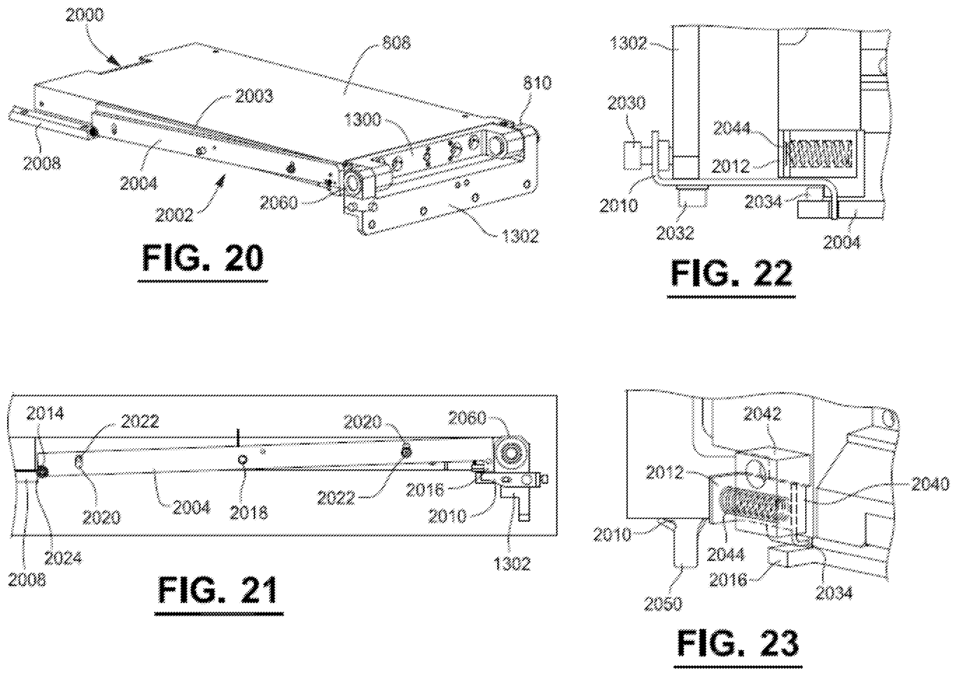

FIGS. 20-23 show a portion 2000 of the slide and pivot assembly 806 including the slide torsion plate 808, hinge assembly 810 and a slide-pivot interlock mechanism 2002. The slide-pivot interlock mechanism 2002 is used to hold the slide and pivot assembly in the fully pulled out state. The slide-pivot interlock mechanism 2002 prevents accidental damage to the corresponding process module bias assembly and/or processing chamber by, for example, a user attempting to dock the bias assembly when the corresponding bias mounting plate is not in a fully non-rotated position. The slide-pivot interlock mechanism 2002 also, for example, prevents pivot motion towards the fully non-rotated position unless the slide is in the fully extended pulled out/open position.

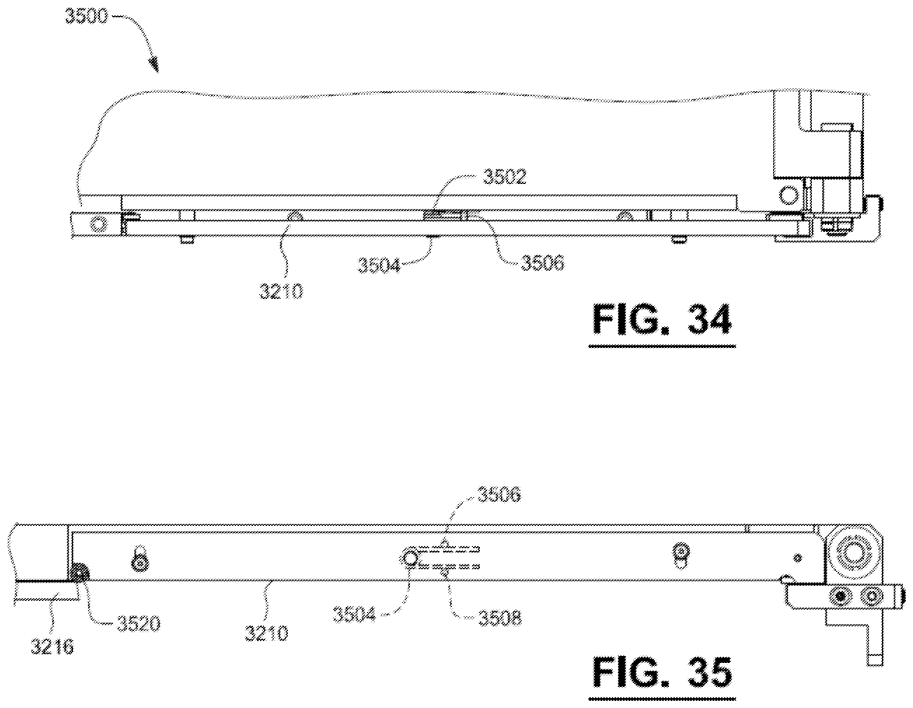

The slide-pivot interlock mechanism 2002 includes an attachment bar 2003, a latch bar 2004, a spring (example of a torsion spring is shown in FIGS. 34-35), a stop strip 2008, an adjustable catch bracket 2010, and a toggle stop bracket 2012. The spring may be a torsion spring or a spring of a different type or may be located away from the latch bar center of rotation. When in a fully pulled out state, a bearing roller 2014 on the latch bar 2004 is moved relative to and past the stop strip 2008 and allows the spring to rotate the latch bar 2004 releasing a hooked end 2016 of the latch bar 2004 from the adjustable catch bracket 2010. In an alternate embodiment, the function of the attachment bar 2003 is made an integral part of the torsion plate 808, and the torsion spring function can be achieved using an extension or compression spring.

The torsion spring is disposed between the attachment bar 2003 and the latch bar 2004 and coiled around a torsion pin 2018. The latch bar 2004 includes two slots 2020 corresponding to a pair of pins 2022. The latch bar 2004 rotational limits are defined by movement of the pins 2022 in the slots 2020. An end 2024 of the stop strip 2008 is angled to allow the bearing roller 2014 to roll along the end 2024. The end 2024 may be angled such that the slide and pivot assembly 806 remains in the fully pulled out state and unless a predetermined amount of lateral force is applied on the process module bias assembly to push in the slide and pivot assembly 806 to a fully pushed in state. When the predetermined amount of force is applied, the bearing roller 2014 rotates causing the latch bar 2004 to rotate against the force of the torsion spring and hook the hooked end 2016 on the adjustable catch bracket 2010. A pull cable or other actuation device may be used to pivot the latch bar 2004 into the closing state, or the latch bar may be pivoted into the closing state by pushing on it directly by hand. This would allow a square end, or reverse angle, on the stop strip for a more positive slide lock in the open position.

The adjustable catch bracket 2010 has screws 2030, 2032 to adjust position of the catch bracket 2010 in respective directions relative to the bias mounting plate member 1302. The latch bar 2004 includes a latch bar stop element 2034, which is used to prevent rotation of the latch bar 2004 while the bias mounting plate member 1302 is rotated away from a fully closed (or 90°) state relative to the slide torsion plate member 1300, as shown in FIG. 23. The latch bar stop element 2034 may be implemented as a pin, a flange, a cut-down semi-circular pin or other part, or other stop element. The toggle stop bracket 2012, which is mounted on the slide torsion plate member 1300, contacts the latch bar stop element 2034 and prevents the latch bar 2004 from rotating into the closed position, except when the hinge is in the fully non-rotated position.

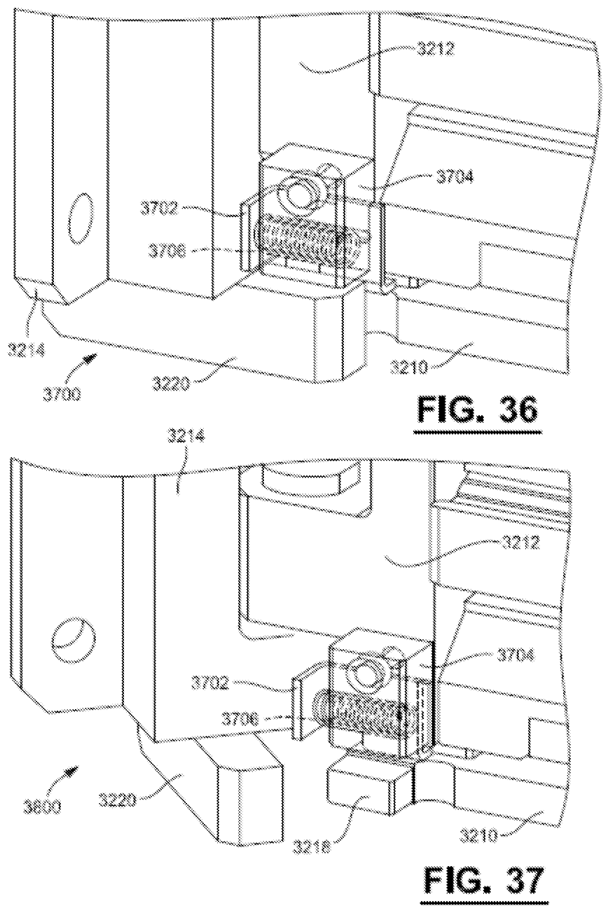

The toggle stop bracket 2012 has multiple “L-shaped” portions and is able to slide relative to the slide torsion plate hinge member 1300 along a notch 2040 in a spring holding block 2042, and guide pins in hinge member 1300. The spring holding block 2042 holds a spring 2044 that slides the toggle stop bracket 2012 towards the bias mounting plate member 1302. As the bias mounting plate member 1302 is pivoted open and away from the slide torsion plate member 1300, the toggle stop bracket 2012 slides to the position shown in FIG. 23 to stop rotation of the latch bar 2004. As the bias mounting plate member 1302 is pivoted closed towards the slide torsion plate member 1300, the toggle stop bracket 2012 slides in an opposite direction to no longer be in contact with the latch bar stop element 2034, which allows the hooked end 2016 to engage a hooked end 2050 of the adjustable catch bracket 2010. An alternative embodiment is illustrated in FIGS. 36-39.

FIGS. 24-25 show an example of a bearing assembly 2500 for a hinge assembly, such as the hinge assembly 810 of FIG. 9. Although a particular bearing assembly is shown, other bearing assemblies may be used. Two of the bearing assembly 2500 may be used for both ends of the hinge assembly 810. The hinge assembly 810 includes the members 1300, 1302. The bearing assembly 2500 includes a pin 2502 that extends through holes 2504, 2506 in the members 1300, 1302, a thrust bearing 2508, a tapered roller bearing assembly 2510, a washer 2512 and a lock nut 2514. The roller bearing assembly 2510 includes an outer cup 2516, containing tapered roller hinge pivot bearings 2518 and an inner cone 2520. The roller bearing assembly 1510 sits in a pocket 2530 of the bias mounting plate member 1302.

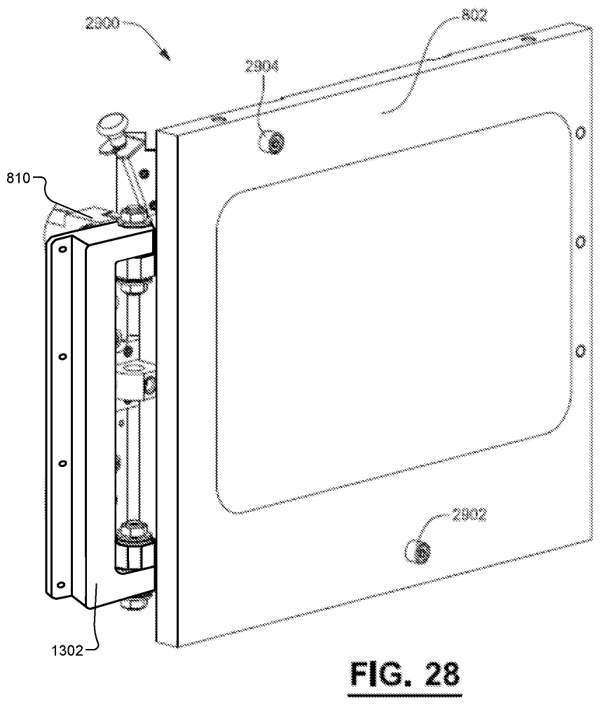

The tapered roller bearing assembly 2510 improves bias alignment and repeatability, as compared with a simple sleeve bearing assembly. The tapered bearing eliminates clearance between hinge member 1302 and pivot shaft 2502. Bearing clearance contributes to position error during and after the hinge tilt adjustment procedure to compensate for bias mounting plate sag angle (FIG. 26). One of the above disclosed alignment pins (e.g., the pin 2904 of FIG. 28) may be referred to as a clocking alignment pin, which serves to properly align the bias mounting plate angle. When bearing clearance related position error is small and negligible, the clocking pin requirement may be removed. Clocking pin removal eases docking and fastening the bias mounting plate 812 to the processing chamber 802 of FIG. 9.

As an alternative to the bearing assembly of FIGS. 24-25, a sleeve or needle bearing assembly may be used. The alternate bearing assembly may include a fastener, such as a pin, which extends through nuts, thrust bearings, a thrust washer, sleeve bushings and holes in the members 1300, 1302. The sleeve bushings may extend out of the holes and include washer-shaped ends, designated 2060 in FIGS. 20 and 21. As an example, the sleeve bushings may be steel backed and/or polytetrafluorethylene (PTFE) sleeve bushings.

FIG. 26 shows the slide and pivot assembly 806 including the hinge assembly 810 and the bias mounting plate 812. Due to weight of the corresponding process module bias assembly and the slide and pivot assembly 806, sag can occur and is illustrated as an example sag angle. An alignment pin 2710 is shown in an opening 2712 of the bias mounting plate 812. FIG. 30 shows how the hinge assembly 810 is adjusted to account for this sag angle using the hinge adjustment fasteners 1310 of FIG. 13.

FIG. 27 shows an alignment pin 2800 and receiving bushing 2802. The alignment pin 2800 is shown in the chamber wall 1814. The receiving bushing 2802 is shown in the bias mounting plate 812. The alignment pin 2800 has a tapered end 2804 and allows for easy alignment and insertion of the alignment pin 2800 in a hole 2806 of the bushing 2802. The bushing 2802 has a rounded end 2807 for ease in sliding the alignment pin 2800 into the bushing 2802. This aligns the bias mounting plate 812 relative to the processing chamber 802 of FIG. 9, prior to tightening closure fasteners, such as fastener (e.g., bolt or screw) 1216 of FIG. 26. In an embodiment, 4 closure fasteners are used to fasten the bias mounting plate 812 to the processing chamber 802. As an example, the bushing 2802 provides up to 30 microns of pin clearance relative to the bushing 2802. In an embodiment, the alignment pin 2800 is on the bias mounting plate 812 and the bushing 2802 is on the chamber wall 1814.

FIG. 28 shows a portion 2900 of the processing chamber 802 of FIG. 9 including the bias plate with alignment pins 2902, 2904. In FIG. 28, the bias mounting plate member 1302 of the hinge assembly 810 is not shown as being attached to the bias mounting plate 812 and is rotated away from the processing chamber 802. The alignment pin 2904 may be referred to as a clocking alignment pin. In one embodiment, the clocking alignment pin 2904 is not included to ease attachment of the bias mounting plate 812 of FIG. 9 to the processing chamber 802, and to ease the hinge tilt adjustment procedure used to align the bushings and pins.

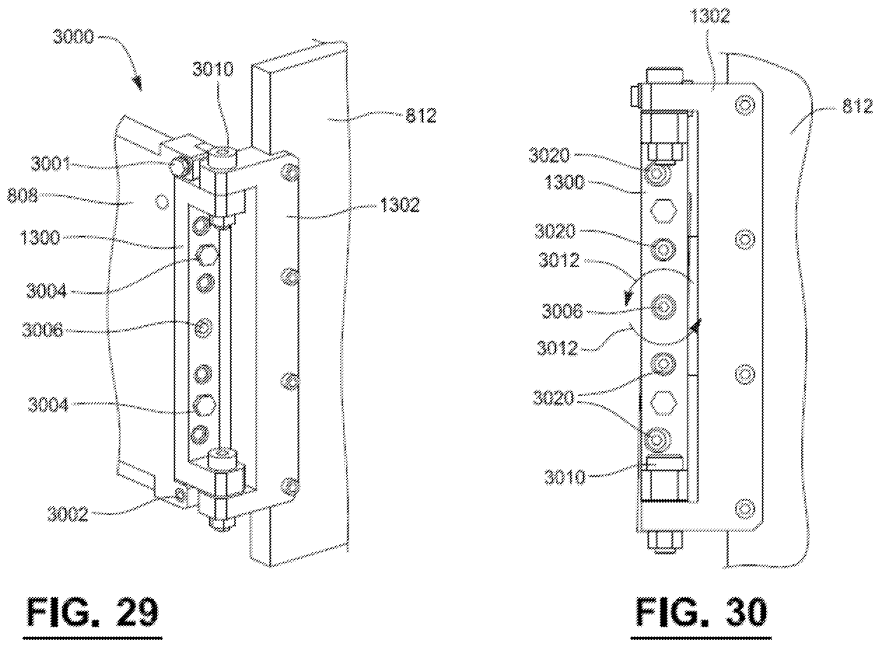

FIGS. 29 and 30 show a hinge assembly 3000 similar to the hinge assembly 810 of FIG. 9. The hinge assembly 3000 includes the members 1300, 1302 attached to the plates 808, 812. The hinge assembly 3000 includes a tilt adjustment screw 3001, a tilt lock screw 3002, or in an alternate embodiment, eccentric tilt adjustment bushings 3004. The slide torsion plate member 1300 is rotatable about a rotation pin 3006 attached to the slide torsion plate 808. The hinge assembly 810 is shown with different hinge pivot fasteners 3010 than in the previous figures associated with the embodiment of FIG. 9.

The tilt adjustment screw 3001 and/or the tilt lock screw 3002 may be turned to tilt the bias mounting plate CCW to compensate for sag and negate slide plate twist. This may be done while under load. Arrows 3012 represent CCW rotation of the slide torsion plate member 1300 about the pin 3006 and corresponding CCW motion of the hinge assembly 3000 and bias mounting plate 812. Hinge fasteners (e.g., bolts or screws) 3020 are included and tightened down after the tilt adjustment screw 3001 has been adjusted.

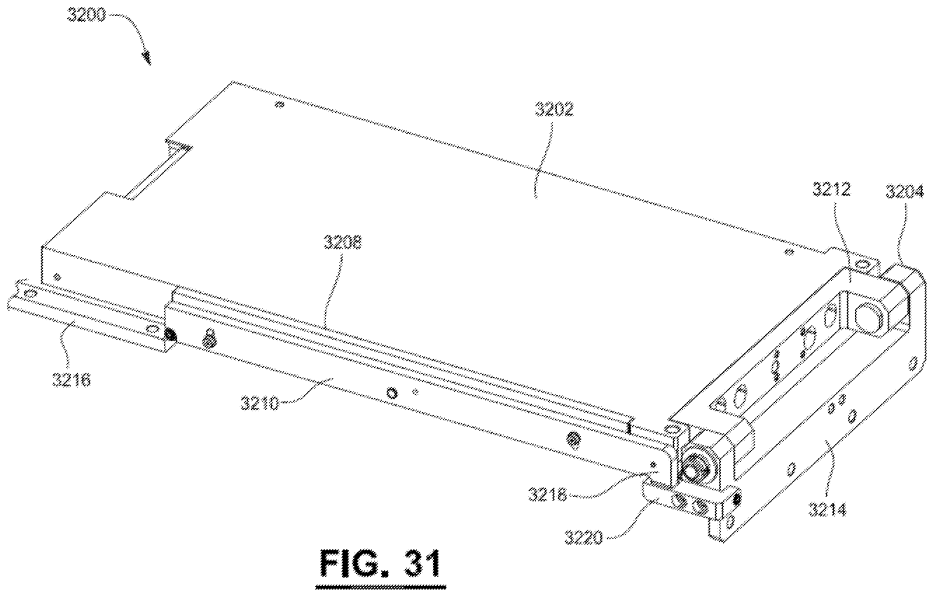

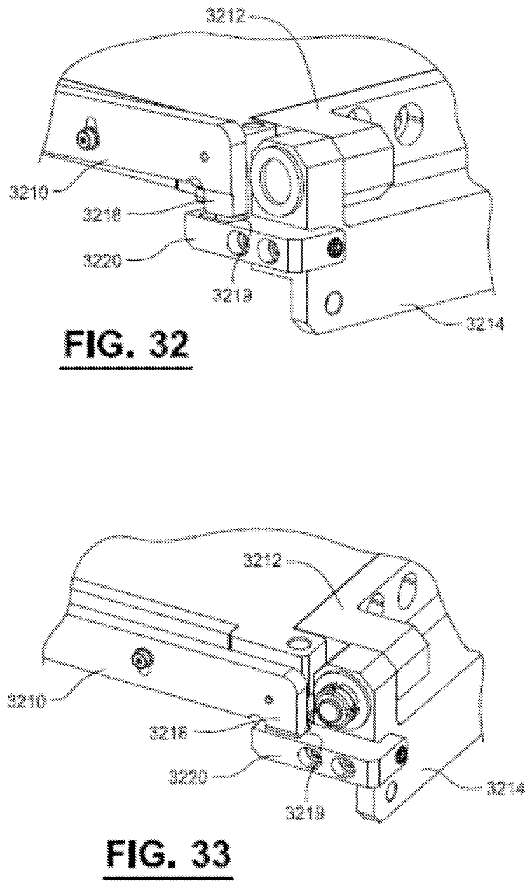

FIGS. 31-33 show a portion 3200 of another slide and pivot assembly including a slide torsion plate 3202, a hinge assembly 3204, an attachment bar 3208, and a latch bar 3210. The hinge assembly 3204 includes a slide torsion plate member 3212 and a bias mounting plate member 3214 that is attached to a bias mounting plate. The latch bar 3210 operates similarly as the latch bar 2004 of FIG. 20 and is held in a fully pulled out state by a stop strip 3216. The latch bar 3210 includes a hooked end 3218 that when engaged is at least partially in a slot 3219 of a catch bracket 3220, which is attached to the bias mounting plate member 3214.

FIGS. 34-35 show a portion 3500 of the slide and hinge assembly 3204 of FIG. 31 illustrating a torsion spring 3502, which is around a rotation pin 3504 and has ends pressed against holding pins 3506, 3508 attached to the latch bar 3210 and the attachment bar 3208. The torsion spring 3502 rotates the latch bar CCW when a bearing roller 3520 clears the stop strip 3216. In an alternate embodiment, an extension spring or other type of spring is utilized to apply rotation force at some distance from the latch bar pivot point. Alternately, the latch bar 3210 can be moved manually without using a spring.

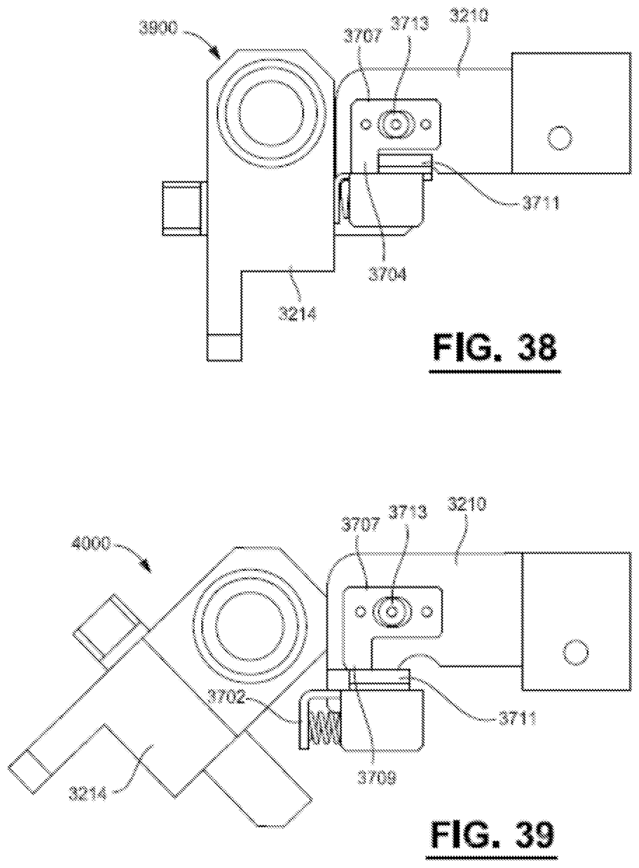

FIGS. 36-39 show portions 3700, 3800, 3900, 4000 of the hinge assembly 3204 of the slide and pivot assembly of FIG. 31. FIG. 36 illustrates the slide and pivot assembly in a non-rotated state with the latch bar 3210 engaged. FIG. 37 illustrates a pivoted state with the latch bar 3210 disengaged. FIG. 38 illustrates a non-rotated state with the latch bar 3210 engaged. FIG. 39 illustrates a pivoted state with latch bar disengaged.

The hinge assembly 3204 includes the members 3212, 3214, the latch bar 3210, the catch bracket 3220, and a toggle stop bracket 3702 that is held by and slides relative to a holding block 3704 and is moved by a spring 3706. The latch bar 3210 includes an adjustable second toggle stop bracket 3707 that is “L-shaped” and includes an end 3709 that is against a tab 3711 of the toggle stop bracket 3702 when the bias mounting plate member 3214 is in an open state as shown in FIGS. 37 and 39 and is alongside of the tab 3711 when the bias mounting plate member 3214 is in a fully non-rotated state as shown in FIGS. 36 and 38. A position of the toggle stop bracket 3707 is adjusted relative to the latch bar 3210 via a fastener 3713.

FIGS. 40-43 show a jack screw assembly 4200 illustrating a jack screw block 4202 in ON (IN) and OFF (OUT) positions and a jack screw 4204 in a fastened and pulled out states. The jack screw assembly 4200 is configured to and functions similar to the jack screw assembly of FIGS. 18-19. The jack screw block 4202 is attached to a bias mounting plate 4218 via fasteners, such as fasteners 1224 of FIG. 19. The fasteners 1224 retain the jack screw block 4202 and allow adequate clearance for the jack screw block 4202 to slide due to weight of the jack screw block 4202. The jack screw block 4202 includes an upper cupped area 4208 to receive a head 4210 of the jack screw 4204 when in a pulled out state. The jack screw block 4202 also includes a solid area 4212 below the upper cupped area 4208, which does not receive the head 4210 of the jack screw 4204, but rather is used to jack the bias mounting plate 4218 off of a processing chamber wall 4220.

The head 4210 may be covered by a head screw cap 4230 having hooked fingers 4232, which prevent the head screw cap from coming off the head 4210. The jack screw 4204 may include a stepped washer 4234 and a non-stepped washer 4236. The stepped washer 4234 includes a protruding ring-shaped portion 4238 that is inserted in an opening of the head screw cap 4230 when on the head 4210, and functions to direct clamping forces to the head 4210 and not to the hooked fingers 4232.

FIGS. 44-46 show a jack screw assembly 4400 illustrating a jack screw block 4402 and a jack screw 4404 in a fastened state. The jack screw assembly 4400 is configured to and functions similar to the other jack screw assemblies disclosed herein. The jack screw block 4402 is attached to a bias mounting plate 4406 via fasteners, such as fasteners 1224 of FIG. 19. The jack screw block 4402 includes an upper cupped area 4408 to receive a head 4410 of the jack screw 4404 when in a pulled out state. The jack screw block 4402 also includes a hollow recessed area 4412 below the upper cupped area 4408, which does not receive the head 4410 of the jack screw 4404, but rather is used to jack the bias mounting plate 4406 off of a processing chamber wall 4413. The hollow recessed area 4412 is configured to hold a wear component 4414. As an example, the wear component 4414 may be a plastic bushing. Pressure is applied in a backside of the wear component 4414 when the jack screw 4404 is rotated CCW to jack the bias mounting plate 4406 off the processing chamber wall 4413. The wear component 4414 is replaceable similar to the head screw cap 4230 of FIG. 43.

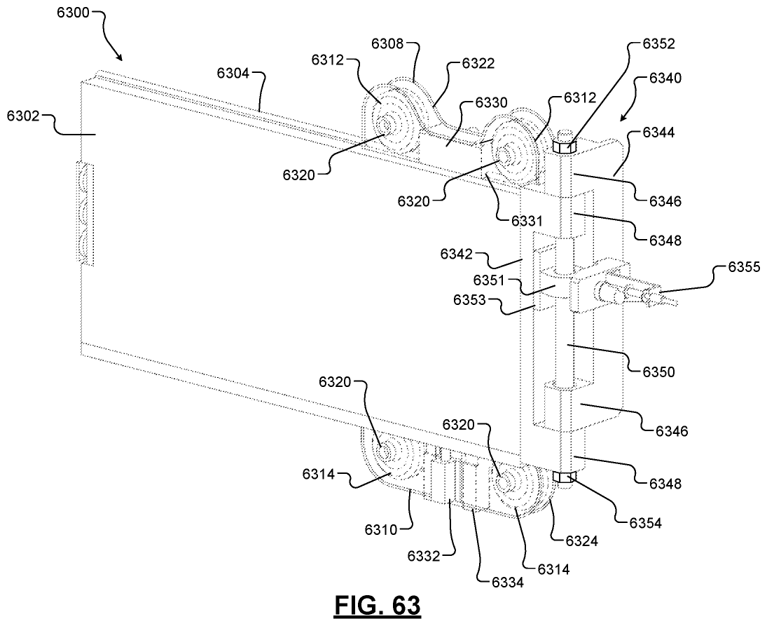

The following FIGS. 47-50 and 53-63 illustrate alternative example embodiments that may replace any of the above-described slide and pivot assemblies and/or portions thereof.

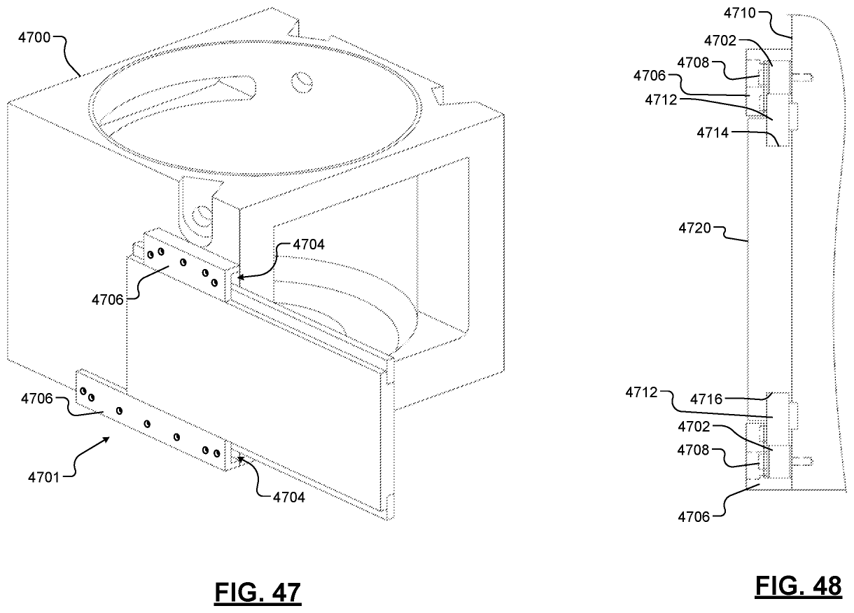

FIGS. 47-48 show a processing chamber 4700 including a portion 4701 of another slide and pivot assembly including cam followers 4702. The cam followers (or rollers) 4702 are attached within channels 4704 formed by the mounting brackets 4706 and a sidewall 4710 of the processing chamber 4700. Fasteners 4708 may extend through the mounting brackets 4706 and through the cam followers 4702 and are threaded into the sidewall 4710 of the processing chamber 4700. The fasteners 4708 attach the cam followers 4702 to the sidewall 4710. Additional fasteners may be included to attach the mounting brackets 4706 to the sidewall 4710. The cam followers 4702 may include bearings. Intermediary spacers (or rails) 4712 may be attached to the slide torsion plate 4720 or integrally formed as part of the slide torsion plate 4720. The intermediary spacers 4712 are disposed between top and bottom edges 4714, 4716 of the torsion plate 4720. The brackets 4706 may be ‘L’-shaped and keep a portion of the torsion plate 4720 between the cam followers 4702.

The torsion plate 4720 has a ‘T’-shaped cross-section and includes a first portion disposed between the intermediary spacers 4712 and a second portion disposed between the mounting brackets 4706. The intermediary spacers 4712 may be integrally formed as part of or be attached to the torsion plate 4720. The torsion plate 4720 and intermediary spacers 4712 slide between the cam followers 4702. The brackets 4706 and intermediary spacers 4712 and may be formed of steel. The torsion plate 4902 may be formed of aluminum.

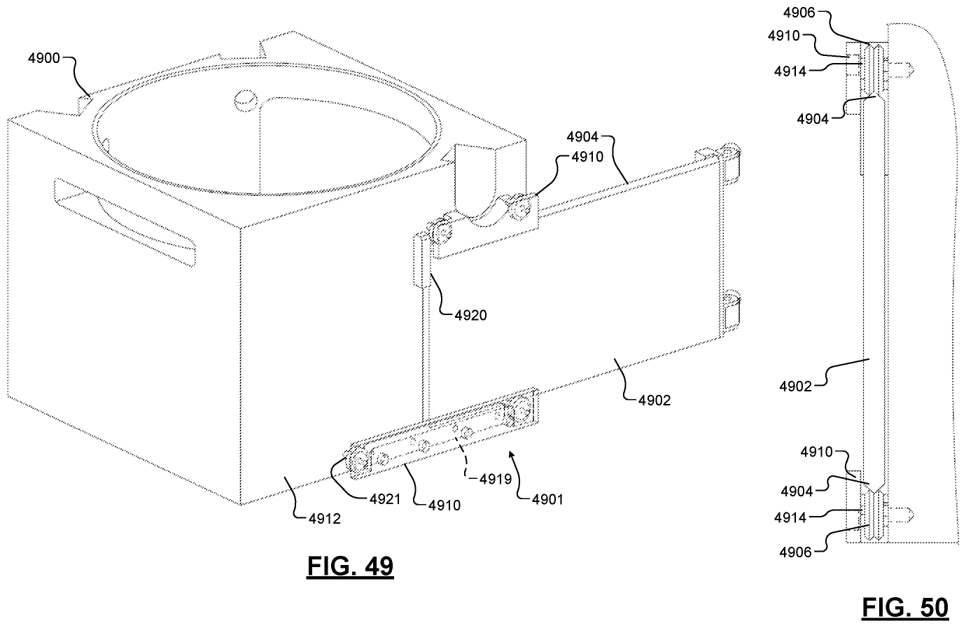

FIGS. 49-50 show a processing chamber 4900 including a portion 4901 of another slide and pivot assembly including torsion plate 4902 with tracks 4904 for ‘V’-grooved cam followers (or track rollers) 4906. The torsion plate 4902 slides on the track rollers 4906. The track rollers 4906 are attached within channels 4908 formed by mounting brackets 4910 and a sidewall 4912 of the processing chamber 4900. Fasteners 4914 may extend through the mounting brackets 4910 and through the track rollers 4906 and are threaded into the sidewall 4912. The fasteners 4914 attach the track rollers 4906 to the sidewall 4912. Additional fasteners may be included to attach the mounting brackets 4910 to the sidewall 4912. The track rollers 4906 may include bearings. The brackets 4910 may be ‘L’-shaped to help keep the tracks 4904 in the ‘V’-shaped grooves of the track rollers 4906, which in turn help keep the torsion plate 4902 between the track rollers 4906.

The slide and pivot assembly may include a center bar 4919 disposed between the track rollers 4906, which are attached to the bottom one of the mounting brackets 4910. The center bar 4919 may direct the torsion plate 4902 to slide onto the back track roller (designated 4921). The slide and pivot assembly includes a stopper 4920 that is attached to the back end of the torsion plate 4902. When the torsion plate 4902 is slid out to a fully out position, the stopper 4920 comes in contact with the upper one of the brackets 4910, which limits and prevents the torsion plate 4902 from being slid out any further.

FIG. 51 show a slide and pivot assembly 5100 illustrating directions of torsional and vertical stiffness of a torsion plate 5102. A bias assembly 5104 is attached to the slide and pivot assembly 5100, which in turn is attached to a processing chamber 5106. During sliding movement of the torsion plate 5102, the torsion plate 5102 may experience torsional and vertical forces due primarily to weight and movement of the bias assembly 5104 relative to the processing chamber 5106. The torsion plate 5102 provides both torsional and vertical stiffness to support the offset weight of the bias assembly 5104.

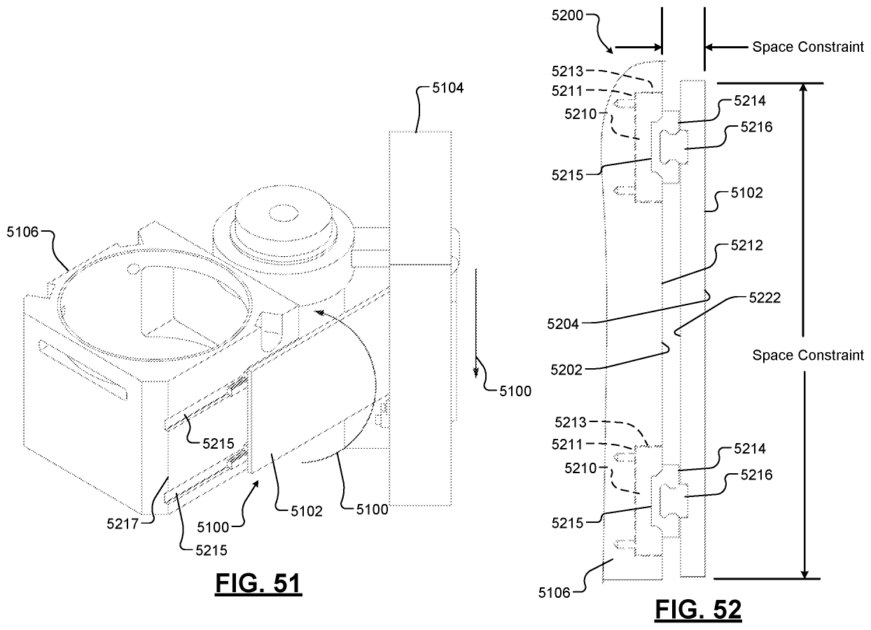

FIG. 52 shows a portion 5200 of the slide and pivot assembly of FIG. 51 illustrating horizontal and vertical space constraints. The horizontal space constraint may refer to a distance from an outer side surface 5202 of the processing chamber 5106 to an outer side surface 5204 of the torsion plate 5102. The outer side surface 5204 of the torsion plate 5102 may be at least a predetermined distance from another processing chamber disposed adjacent to the processing chamber 5106. The vertical space constraint may refer to (i) a lowermost point (or height) to which the torsion plate may extend, and (ii) an uppermost point (or height) to which the torsion plate may extend.

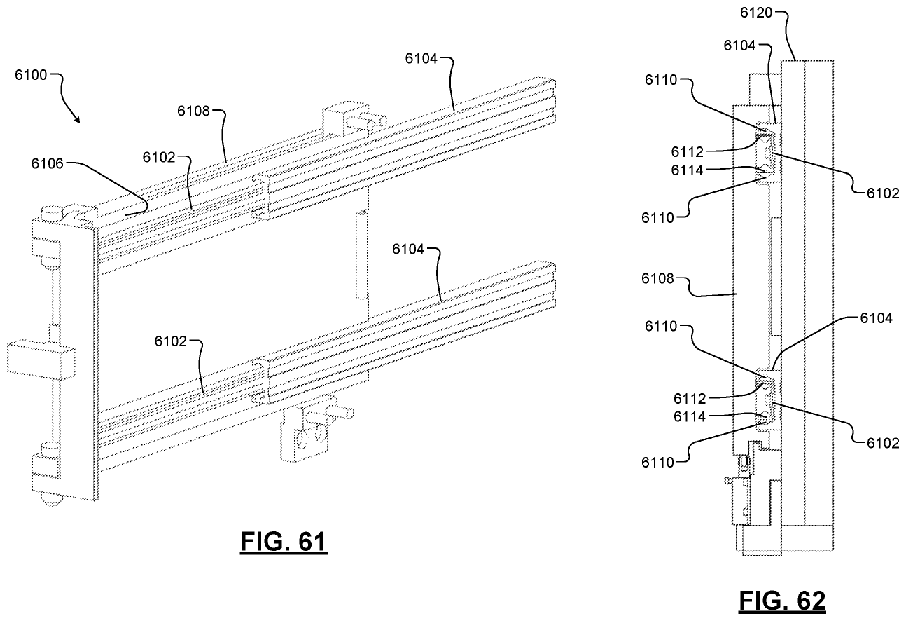

In FIG. 52, bearing blocks 5210 are shown disposed in recessed areas of a sidewall 5212. The bearing blocks 5210 include the hidden portions 5213 and the non-hidden portions 5214. The portions 5213 are hidden in FIG. 52 because these portions are in recessed areas 5211 of the sidewall 5212, which do not fully extend across the sidewall 5212. From the opposite (or front) end of the sidewall 5212, the recessed areas 5211 that include the hidden portions 5213 are visible. Other recessed areas 5215 are shown and extend from a back edge 5217 of the sidewall 5212 to the recessed areas 5211 in which the bearing blocks 5210 are located. The bearing blocks 5210 are attached to the sidewall 5212 . The bearing blocks 5210 may be similar to and operate similarly as the bearing blocks shown in FIGS. 59-60. Rails 5216 are attached to recessed areas of an inner surface 5222 of the torsion plate 5102. The rails 5216 engage with and slide in a portion of the bearing blocks 5210 allowing the torsion plate 5102 to be slide relative to the sidewall 5212 between fully retracted and fully pulled-out states. The engagement of the rails 5216 with the bearing blocks 5210 prevents the rails from be pulled away from the bearing blocks 5210 in a direction perpendicular to a slide direction of the rails 5216 by, for example, the torsion plate 5102.

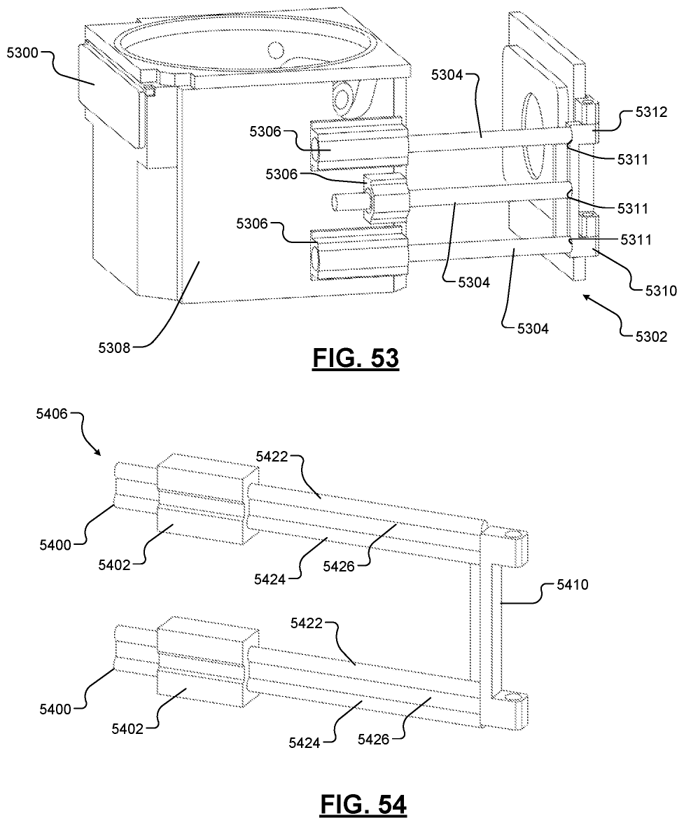

FIG. 53 shows a processing chamber 5300 including another slide and pivot assembly 5302 with cylindrical-shaped rails 5304 and corresponding rail guides 5306. The rail guides 5306 are attached to a sidewall 5308 of the processing chamber 5300. The rails 5304 slide in the rail guides 5306 and are attached at front ends to a hinge assembly 5310, which in turn is attached to a bias plate 5312. Font ends of the rails 5304 may be slid into cylindrically-shaped slots 5311 in a slide rail member 5312 of the hinge assembly 5310. The front ends of the rails 5304 may be fastened and/or otherwise connected to the slide rail member 5312. The rail guides 5306 may include bushings and/or bearings for sliding the rails 5304. The size of the rails 5304 and rail guides 5306 are selected to minimize and/or prevent rail twist. For increased rigidity, the rails 5304 and the rail guides 5306 may be replaced with web rails 5400 and corresponding rail guides 5402, which are shown in FIG. 54.

FIG. 54 show a portion 5406 of another slide and pivot assembly including the web rails 5400 and corresponding rail guides 5402. The web rails 5400 may be attached to a hinge assembly (a portion 5410 of which is shown in FIG. 54). The rail guides 5402 are blocks that may be attached to a sidewall of a processing chamber via fasteners. Each of the web rails 5400 includes cylindrical-shaped longitudinal edges 5422, 5424 with a longitudinal member 5426 extending therebetween. The rail guides 5402 may include bushings and/or bearings for sliding the rails 5400.

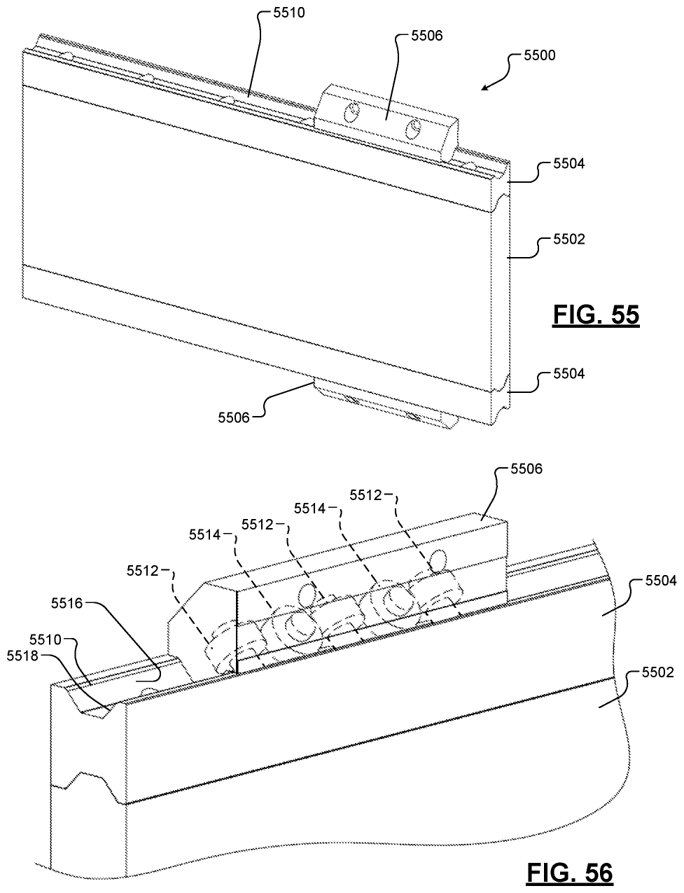

FIGS. 55-56 show a portion 5500 of another slide and pivot assembly including a torsion plate 5502 with top and bottom edge roller guides 5504 and corresponding roller blocks 5506. The roller blocks 5506 may be attached to a sidewall of a processing chamber. Each of the roller guides 5504 includes a recessed ‘V’-shaped track 5510 along which cross-connected rollers 5512, 5514 roll. The rollers 5512, 5514 may include bearings and fasteners for attaching to the roller guides 5504. The first rollers 5512 roll on a first side surface 5516 of the track 5510 and the second rollers 5514 roll on a second side surface 5518 of the track 5510. The second rollers 5514 and/or corresponding fasteners may be arranged perpendicular relative to the first rollers 5512 and/or corresponding fasteners. The cross-connected rollers 5512, 5514 maintain the torsion plate 5502 is a same lateral position relative to the sidewall of the processing chamber. The torsion plate 5502 may be moved relative to the roller blocks 5506 between fully extended and fully retracted positions in a similar manner as the other torsion plates referred to herein.

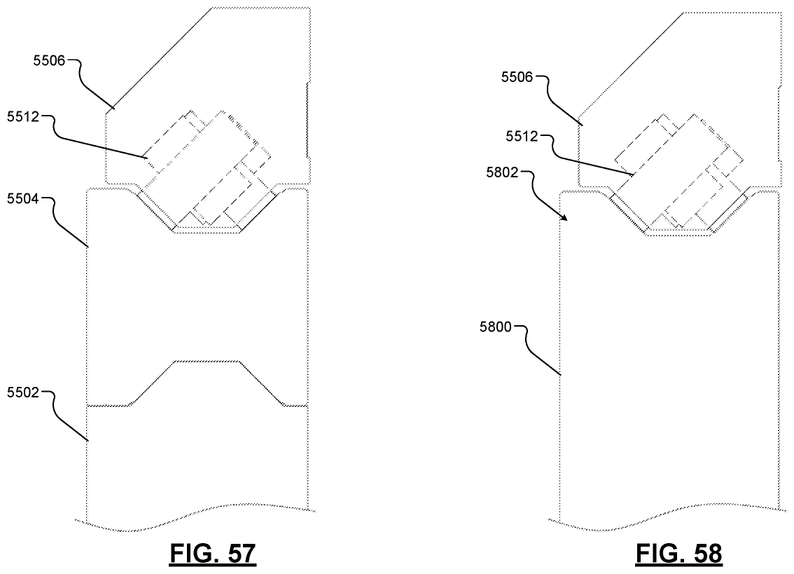

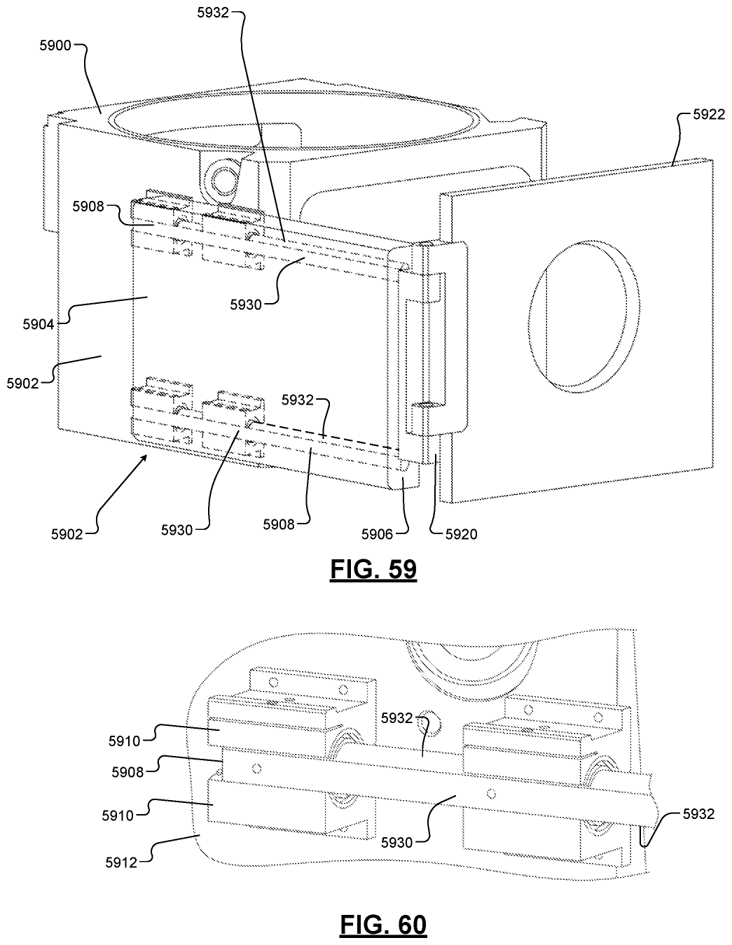

FIG. 57 shows the edge roller guide 5504 and the roller block 5506 including one of the rollers 5512. The edge roller guide 5504 is attached to a top or bottom edge of the torsion plate 5502. As an alternative, the edge roller guide 5504 may be integrally formed as part of the torsion plate 5502. FIG. 58 shows an example of this including a torsion plate 5800 with an integrally formed edge roller guide portion 5802 with a track 5804 for a roller 5512. The roller 5512 is attached to the roller block 5506.

FIGS. 59-60 show a processing chamber 5900 including another slide and pivot assembly 5902 including a ‘C’-shaped torsion plate 5904 with an end cap 5906 and support rails 5908 sliding relative to open bearing blocks 5910. The bearing blocks 5910 are attached to a sidewall 5912 of a processing chamber 5900. The bearing blocks 5910 include open bearings for sliding the support rails 5908 relative to the sidewall 5912. The torsion plate 5904 and the end cap 5906 may be formed of steel. A hinge assembly 5920 may be attached to the end cap 5906 and to a bias plate 5922.

Each of the support rails 5908 includes a flat side 5930 and a curved portion 5932. The curved opposing sides contact the bearing blocks 5910. The flat sides 5930 face away from the sidewall 5912 and is visible through rectangular-shaped openings in the corresponding ones of the bearing blocks 5910. In one embodiment, the bearing blocks 5910 of each of the support rails 5908 are combined to provide single longer bearing blocks than shown in FIGS. 59-60. For example, in the current example, four bearing blocks are shown (two for each support rail). Two longer bearing blocks may be provided to replace the four bearing blocks.

FIG. 61 shows a portion 6100 of another slide and pivot assembly including telescopic rails 6102 and slides 6104. The telescopic rails 6102 are attached to an inner side 6106 of a torsion plate 6108. The slides 6104 have a ‘C’-shaped cross-section and slide on the telescopic rails 6102 via bearings 6110. The bearings 6110 may be (i) disposed between upper and lower sides 6112, 6114 of the telescopic rails 6102 and upper and lower inner sides of the slides 6104, (ii) held in place by the telescopic rails 6102, and/or (iii) held in place by the slides 6104. The slides 6104 are attached to a sidewall 6120 of a processing chamber. The telescopic rails 6102 and/or bearings 6110 may be greased (or otherwise lubricated). Sliding the torsion plate 6108 from fully retracted to fully extended states includes sliding the telescopic rails 6102 relative to the slides 6104. In another embodiment, the telescopic rails are attached to the sidewall 6120 and the slides 6104 are attached to the torsion plate 6108. A slide lock assembly 6200 may be disposed below the torsion plate 6108 and be attached to the sidewall 6120 and is used to lock and prevent sliding movement of the torsion plate 6108. The slide lock assembly 6200 is configured similarly to and operates similarly as the slide lock assembly 1101 of FIG. 12.

FIG. 63 shows a portion 6300 of another slide and pivot assembly including a torsion plate 6302 with top and bottom edge rails (the top one of which is designated 6304) for roller assemblies 6308, 6310 with ‘V’-shaped grooved track rollers 6312, 6314. The edge rails ride on ‘V’-shaped grooves of the track rollers 6312, 6314. The ‘V’-shaped grooves aid in maintaining lateral position of the torsion plate 6302 relative to a sidewall of a processing chamber.

The roller assemblies 6308, 6310 may be attached to the sidewall of the processing chamber via (i) fasteners 6320, 6322, which extend through housings 6322, 6324 of the slide assemblies 6308, 6310 and the track rollers 6312, 6314 and screw into the sidewall; and/or (ii) other fasteners (not shown) extending through the housings 6322, 6324 and a center block 6330 and a slide lock assembly 6332. The center block 6330 is disposed between the track rollers 6312 and may include a ‘V’-shaped groove 6331 through which the top edge rail 6304 slides. The slide lock assembly 6332 is disposed between the track rollers 6314 and is used to lock and prevent sliding movement of the torsion plate 6302. The slide lock assembly 6332 is configured similarly to and operates similarly as the slide lock assembly 1101 of FIG. 12. A block 6334 of the slide lock assembly 6332 may include a ‘V’-shaped groove similar as the ‘V’-shaped groove of the center block 6330 for the bottom edge rail. The blocks 6330 and 6334 function as redundant supports to retain the torsion plate 6302 in the event of V-wheel bearing failure.

FIGS. 26, 59 and 63 show hinge assemblies having a “lift-off” design for lifting off a bias plate and corresponding bias mounting plate member of the hinge assembly from a slide torsion plate member of the hinge assembly. Referring to FIG. 63, which shows a hinge assembly 6340 including a slide torsion plate member 6342 attached to the torsion plate 6302 and a bias mounting plate member 6344. The members 6342, 6344 are each ‘U’-shaped, where fingers 6346 of the bias mounting plate member 6344 sit on respective fingers 6348 of the slide torsion plate member 6342. In the example shown, a shaft 6350 extends through the fingers 6346, 6348 and is held in place relative to the members 6342, 6344 by nuts 6352, 6354 that are on threaded ends of the shaft 6350. The shaft 6350 passes through a circular member 6351 of a pivot block (similar to pivot block 1704 of FIG. 17) that is fastened via a plate 6353 to the slide torsion plate member 6342 between one of the fingers 6348 and one of the fingers 6346. The circular member 6351 is attached to the plate 6353. A pivot lock assembly 6355 engages with the circular holding member 6351, similarly as the pivot lock assembly 814 of FIG. 17. The shaft 6350 extends through the circular member 6351. A corresponding bias plate (not shown in FIG. 63) that is attached to the bias mounting plate member 6344 is able to be removed along with the bias mounting plate member 6344 from the slide torsion plate member 6342 by simply removing the nuts 6352, 6354 and the shaft 6350. Although the shaft 6350 is shown, the shaft may be replaced with upper and lower pins similar to the pin 2502 shown in FIGS. 24-25.

Although certain fasteners are referred to above, various additional fasteners (e.g., screws, nuts, pins, bolts, etc.) may be included in the above examples, some of which are shown in the figures.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A slide and pivot assembly for a process module bias assembly of a substrate processing system, the slide and pivot assembly comprising:
a slide torsion plate;
one or more rails configured to attach to the slide torsion plate or a processing chamber or be integrally formed as part of the slide torsion plate or processing chamber;
bearings disposed adjacent to the one or more rails;
a bias mounting plate configured to hold a portion of a process module for processing a substrate; and
a hinge assembly attached to the slide torsion plate and the bias mounting plate,
wherein the slide torsion plate, the bias mounting plate and the hinge assembly are configured to slide via the one or more rails and bearings in a lateral direction relative to the processing chamber, and
wherein the bias mounting plate is configured to pivot relative to the slide torsion plate while the slide and pivot assembly is in at least a partially pulled out state.

2. The slide and pivot assembly of claim 1, wherein:
the hinge assembly comprises
a first hinge member attached to the slide torsion plate, and
a second hinge member attached to the bias mounting plate and connected to pivot relative to the first hinge member; and
the bias mounting plate and the second hinge member are configured to pivot relative to the slide torsion plate and the first hinge member while the slide and pivot assembly is in a fully pulled out state.

3. The slide and pivot assembly of claim 2, further comprising a pin attached to the slide torsion plate,
wherein the first hinge member is configured to rotate relative to the pin to compensate for sag in the bias mounting plate.

4. The slide and pivot assembly of claim 3, wherein the hinge assembly includes one or more adjustment screws for adjusting a tilt angle of the first hinge member relative to the slide torsion plate.

5. The slide and pivot assembly of claim 2, further comprising a motion interlock mechanism attached to the slide torsion plate and configured to:
hold the slide torsion plate, the hinge assembly and the bias mounting plate in a pulled out state relative to the processing chamber; and
permit the slide torsion plate, the hinge assembly and the bias mounting plate to be slid from a pulled out position to a pushed in position if a predetermined amount of lateral force is applied on the bias mounting plate.

6. The slide and pivot assembly of claim 5, wherein the motion interlock mechanism is configured to:
prevent the second hinge member and the bias mounting plate from pivoting relative to the first hinge member and slide torsion plate when in an engaged state; and
permit the second hinge member and the bias mounting plate to pivot relative to the first hinge member and slide torsion plate when in a disengaged state.

7. The slide and pivot assembly of claim 5, wherein the motion interlock mechanism comprises:
an attachment bar attached to the slide torsion plate; and
a latch bar rotatable relative to the attachment bar to a disengaged position when the slide torsion plate is in a pulled out state.

8. The slide and pivot assembly of claim 7, wherein:
the motion interlock mechanism further comprises a catch bracket attached to the second hinge member; and
the latch bar is configured to
engage with the catch bracket when the bias mounting plate is in a fully non-rotated state and the slide torsion plate is pushed in from a fully pulled out position; and
disengage with the catch bracket when the slide torsion plate is pulled out to the fully pulled out position.

9. The slide and pivot assembly of claim 8, wherein:
the motion interlock mechanism further comprises a toggle stop bracket and a spring;
the latch bar includes a stop flange or pin;
the spring slides the toggle stop bracket to contact the latch bar, which prevents rotation of the latch bar from a slide locked position and prevents engagement of the latch bar with the catch bracket when the second hinge member is pivoted away from a closed position; and
the second hinge member, when transitioned to the closed position, pushes the toggle stop bracket, which compresses the spring and moves the toggle stop bracket to allow rotation of the latch bar out of the slide locked position and to allow engagement of the latch bar with the catch bracket.

10. The slide and pivot assembly of claim 1, wherein the one or more rails includes two rails mounted on the slide torsion plate and configured to ride on bearing blocks mounted on the processing chamber.

11. The slide and pivot assembly of claim 1, wherein the hinge assembly comprises a pivot lock assembly for locking the hinge assembly in a plurality of states including a closed state and an open state.

12. The slide and pivot assembly of claim 1, further comprising a slide lock assembly for locking the slide torsion plate relative to the processing chamber in a plurality of states including a pushed in state and a pulled out state.

13. The slide and pivot assembly of claim 12, wherein the slide lock assembly comprises a plunger and roller that extends into notches in the slide torsion plate.

14. The slide and pivot assembly of claim 1, wherein the bias mounting plate closes off an open side of the processing chamber.

15. The slide and pivot assembly of claim 1, further comprising a jack screw assembly attached to the bias mounting plate and configured to detach the bias mounting plate from the processing chamber.

16. The slide and pivot assembly of claim 15, wherein the jack screw assembly comprises:
a jack screw block attached to the bias mounting plate; and
a jack screw extending into the jack screw block and through the bias mounting plate and coupling to the processing chamber.

17. The slide and pivot assembly of claim 16, wherein the jack screw block has two positions relative to the jack screw including a first position associated with attaching the bias mounting plate to the processing chamber and a second position associated with jacking the bias mounting plate off of the processing chamber.

18. The slide and pivot assembly of claim 16, further comprising:
an alignment pin; and
a bushing configured to receive the alignment pin,
wherein the jack screw is configured to when turned
pull or push the alignment pin into the bushing to align the bias mounting plate relative to the processing chamber, and
release the alignment pin from the bushing when opening the processing chamber.

19. The slide and pivot assembly of claim 1, further comprising:
one or more alignment pins attached to the processing chamber or the bias mounting plate; and
one or more bushings to receive respectively the one or more alignment pins,
wherein the one or more alignment pins, when received in the one or more bushing, align the bias mounting plate to the processing chamber.

20. The slide and pivot assembly of claim 1, wherein the hinge assembly includes one or more bearing assemblies.

21. The slide and pivot assembly of claim 1, further comprising:
cam followers configured to attach to the processing chamber; and
a plurality of brackets configured to attach to the processing chamber,
wherein
the one or more rails comprise two intermediary members attached to or integrally formed as part of the slide torsion plate and extending laterally along a top edge and a bottom edge of the slide torsion plate,
the plurality of brackets configured to form channels with a sidewall of the processing chamber and retain the slide torsion plate from moving away from the processing chamber,
the cam followers are disposed in the channels, and
the slide torsion plate and the intermediary members slide via the cam followers and relative to the processing chamber and the plurality of brackets.

22. The slide and pivot assembly of claim 1, further comprising:
a plurality of track rollers configured to attach to the processing chamber and including ‘V’-shaped grooves; and
a plurality of brackets configured to attach to the processing chamber and forming channels with a sidewall of the processing chamber, the plurality of brackets retain the slide torsion plate from moving away from the processing chamber,
wherein
the one or more rails are attached to or integrally formed as part of the slide torsion plate and slide in the ‘V’-shaped grooves, and
the slide torsion plate slides via the one or more rails and the plurality of track rollers relative to the processing chamber.

23. The slide and pivot assembly of claim 1, further comprising a plurality of roller blocks, wherein:
the plurality of roller blocks comprise
a first set of rollers, and
a second set of rollers cross-connected relative to the first set of rollers;
the one or more rails are attached to the slide torsion plate; and
the slide torsion plate slides via the first set of rollers and the second set of rollers relative to the plurality of roller blocks.

24. The slide and pivot assembly of claim 23, wherein:
the one or more rails comprise two rails disposed on a top edge and a bottom edge of the slide torsion plate;
each of the two rails comprises a ‘V’-shaped groove;
the first set of rollers roll along first surfaces of the ‘V’-shaped grooves; and
the second set of rollers roll along second surfaces of the ‘V’-shaped grooves.

25. The slide and pivot assembly of claim 24, wherein the one or more rails are attached to the slide torsion plate via fasteners.

26. The slide and pivot assembly of claim 24, wherein the one or more rails are integrally formed as part of the slide torsion plate.

27. The slide and pivot assembly of claim 1, further comprising:
an end plate; and
a plurality of bearing blocks configured to be mounted on the processing chamber,
wherein
the slide torsion plate is ‘C’-shaped and attached to the end plate,
the bearing blocks comprise the bearings, and
the one or more rails includes two rails mounted on the slide torsion plate and configured to ride on the bearings of the bearing blocks.

28. The slide and pivot assembly of claim 1, further comprising slides configured to attach to the processing chamber, wherein:
the one or more rails are telescopic rails attached to the slide torsion plate; and
the bearings are disposed between the one or more telescopic rails and the slides allowing the slide torsion plate to slide relative to the slides and the processing chamber.

29. The slide and pivot assembly of claim 1, further comprising slides attached to the slide torsion plate, wherein:
the one or more rails are telescopic rails configured to attach to the processing chamber; and
the bearings are disposed between the one or more rails and the slides allowing the slide torsion plate to slide relative to the telescopic rails and the processing chamber.

30. The slide and pivot assembly of claim 1, further comprising roller assemblies with ‘V’-shaped grooved track rollers, wherein:
the one or more rails are integrally formed as part of the slide torsion plate;
the slide assemblies are configured to attach to the processing chamber; and
the one or more rails slide relative to the ‘V’-shaped grooved track rollers.

31. The slide and pivot assembly of claim 30, wherein one of the roller assemblies comprises a slide lock assembly configured to prevent the slide torsion plate from sliding relative to the processing chamber.

32. The slide and pivot assembly of claim 30, wherein:
at least one of the roller assemblies comprises a block with a groove in which one of the one or more rails slides; and
the block functions as a support to retain the slide torsion plate.

33. A substrate processing system comprising:
the slide and pivot assembly of claim 1;
the processing chamber; and
a substrate support attached to the bias mounting plate and configured to hold the substrate.

34. A slide and pivot assembly for a process module bias assembly of a substrate processing system, the slide and pivot assembly comprising:
a plurality of bearing blocks configured to attach to a processing chamber and comprising bearings;
a plurality of rails configured to slide relative to the plurality of bearing blocks via the bearings;
a bias mounting plate configured to hold a portion of a process module for processing a substrate; and
a hinge assembly attached to the plurality of rails and the bias mounting plate,
wherein the bias mounting plate and the hinge assembly are configured to slide via the plurality of rails and bearings in a lateral direction relative to the processing chamber, and
wherein the bias mounting plate is configured to pivot relative to the plurality of rails while the slide and pivot assembly is in at least a partially pulled out state.

35. The slide and pivot assembly of claim 34, wherein the plurality of rails comprise:
a first rail;
a second rail disposed below the first rail; and
a third rail disposed below the second rail.

36. The slide and pivot assembly of claim 34, wherein the plurality of rails are cylindrically-shaped rails.

37. The slide and pivot assembly of claim 34, wherein:
the plurality of rails comprise web rails; and
each of the web rails includes cylindrically-shaped top and bottom edges extending along and attached to a longitudinal member.

38. A tool comprising:
a wafer transfer module;
a first row of stations on a first side of the wafer transfer module; and
a second row of stations on a second side of the wafer transfer module,
wherein
the wafer transfer module is configured to transfer substrates to and from the first row of stations and the second row of stations, and
each station in the first row of stations and the second row of stations comprises
a processing chamber,
a slide and pivot assembly attached to the processing chamber, and
a bias assembly attached to the slide and pivot assembly and a substrate support, and configured to be pulled out and pivoted away from the processing chamber via the slide and pivot assembly.

39. The tool of claim 38, wherein each of the slide and pivot assemblies is configured to transition from a closed state to pulled out and pivoted state to remove a corresponding one of the substrate supports from a corresponding one of the processing chambers and pivot the corresponding one of the substrate supports away from a corresponding one of the processing chambers.

40. The tool of claim 38, wherein the wafer transfer module comprises a robot for transferring the substrates to and from some of the first row of stations and the second row of stations.

41. The tool of claim 40, wherein the wafer transfer module is attached to an equipment front end module and load lock and transfers the substrates from the equipment front end module and load lock to the first row of stations and the second row of stations.

42. The tool of claim 40, wherein the robot is configured to transfer the substrates between a buffer and the some of the first row of stations and the second row of stations.

43. The tool of claim 38, wherein each of the first row of stations and the second row of stations comprises a vertical arrangement of a radio frequency generator and gas box, a top plate assembly, a corresponding one of the processing chambers, and a vacuum pump.

44. The tool of claim 38, wherein each of the slide and pivot assemblies comprises:
a slide torsion plate;
one or more rails and bearings configured to attach to the slide torsion plate or corresponding one of the processing chambers;
a bias mounting plate configured to hold a portion of a process module for processing one of the substrates; and
a hinge assembly attached to the slide torsion plate and the bias mounting plate,
wherein the slide torsion plate, the bias mounting plate and the hinge assembly are configured to slide via the one or more rails and bearings in a lateral direction relative to the corresponding one of the processing chambers, and
wherein the bias mounting plate is configured to pivot relative to the slide torsion plate while the slide and pivot assembly is in at least a partially pulled out state.

45. The slide and pivot assembly of claim 44, wherein:
the hinge assembly of each of the slide and pivot assemblies comprises
a first hinge member attached to a corresponding one of the slide torsion plates, and
a second hinge member attached to a corresponding one of the bias mounting plates and connected to pivot relative to the first hinge member; and
the corresponding one of the bias mounting plates and the second hinge member are configured to pivot relative to the corresponding one of the slide torsion plates and the first hinge member while the slide and pivot assembly is in at least a partially pulled out state.
